(19) United States
(12) Patent Application Publication
(10) Pub. No.: US 2026/0190755 A1
(43) Pub. Date: Jul. 2, 2026

(54) DISPLAY DEVICE AND ELECTRONIC DEVICE COMPRISING THE SAME

(71) Applicant: Samsung Display Co., Ltd., Yongin-Si (KR)

(72) Inventors: Dong Uk KIM, Yongin-si (KR); Hyun Chul PARK, Yongin-si (KR); Lok Gam JUNG, Yongin-si (KR); Dal Rae JIN, Yongin-si (KR)

(21) Appl. No.: 19/324,130

(22) Filed: Sep. 10, 2025

(30) Foreign Application Priority Data
Jan. 2, 2025 (KR) 10-2025-0000394

(51) Int. Cl. H10K 59/80; H10K 50/19; H10K 59/122

(52) U.S. Cl. CPC H10K 59/80516; H10K 50/19; H10K 59/122

(57) ABSTRACT

Provided is a display device and an electronic device comprising the same. According to various embodiments of the present disclosure, a display device comprises a first electrode including a first sub-electrode and a second sub-electrode located on the first sub-electrode, a light emitting stack located on the first electrode, a second electrode located on the light emitting stack, and a first residual film located between the first sub-electrode and the second sub-electrode.

### CROSS-REFERENCE TO RELATED APPLICATION

This application claims priority from Korean Patent Application No. 10-2025-0000394 filed on 2025 Jan. 2 in the Korean Intellectual Property Office, and all the benefits accruing therefrom under 35 U.S.C. 119, the contents of which in its entirety are incorporated herein by reference.

### BACKGROUND

### 1. Technical Field

The present disclosure relates to a display device and an electronic device comprising the same.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is located on a semiconductor wafer substrate including complementary metal oxide semiconductor (CMOS).

### SUMMARY

Aspects of the present disclosure provide a display device capable of providing high-resolution images.

Aspects of the present disclosure also provide an electronic device capable of providing high-resolution images.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to various embodiments of the present disclosure, a display device comprises a first electrode including a first sub-electrode and a second sub-electrode located on the first sub-electrode, a light emitting stack located on the first electrode, a second electrode located on the light emitting stack, and a first residual film located between the first sub-electrode and the second sub-electrode.

According to various embodiments of the present disclosure, at least a part of a bottom surface of the second sub-electrode may be exposed by the first residual film.

According to various embodiments of the present disclosure, an undercut structure may be located between the first sub-electrode and the second sub-electrode on one side of the first residual film.

According to various embodiments of the present disclosure, one side surface of the first residual film may be located closer to a center of an emission area than a first side surface of the second sub-electrode.

According to various embodiments of the present disclosure, on one side of the first residual film, a bottom surface of the second sub-electrode and one side surface of the first residual film may comprise the undercut structure.

According to various embodiments of the present disclosure, on one side of the first residual film, a top surface of the first sub-electrode and one side surface of the first residual film may comprise the undercut structure.

According to various embodiments of the present disclosure, the display device may further comprise a first pixel defining film located on one side of the first sub-electrode, wherein the first residual film and the first pixel defining film include a same material.

According to various embodiments of the present disclosure, a first undercut structure may be located between the first sub-electrode and the second sub-electrode on one side of the first residual film, and a second undercut structure may be located between the first sub-electrode and the second sub-electrode on an opposite side of the first residual film.

A display device comprises a first electrode including a first sub-electrode and a second sub-electrode located on the first sub-electrode, a light emitting stack located on the first electrode, a second electrode located on the light emitting stack, and a first pixel defining film located between the first sub-electrode and the second sub-electrode, wherein at least a part of a bottom surface of the second sub-electrode may be located to be in contact with the first pixel defining film.

According to various embodiments of the present disclosure, at least a part of the bottom surface of the second sub-electrode may be exposed by the first pixel defining film.

According to various embodiments of the present disclosure, an undercut structure may be located between the first sub-electrode and the second sub-electrode on one side of the first pixel defining film.

According to various embodiments of the present disclosure, the first pixel defining film may comprise a first side surface and a second side surface located further away from a center of an emission area than the first side surface, wherein the first side surface of the first pixel defining film and the bottom surface of the second sub-electrode may comprise the undercut structure.

According to various embodiments of the present disclosure, the first pixel defining film may comprise a first top surface and a second top surface located further away from a topmost surface of the second sub-electrode than the first top surface, wherein the first side surface, the second top surface of the first pixel defining film, and the bottom surface of the second sub-electrode may comprise the undercut structure.

According to various embodiments of the present disclosure, on one side of the first pixel defining film, one side surface of the first pixel defining film and a top surface of the first sub-electrode may comprise the undercut structure.

According to various embodiments of the present disclosure, a first undercut structure may be located between the first sub-electrode and the second sub-electrode on one side of the first pixel defining film, and a second undercut structure may be located between the first sub-electrode and the second sub-electrode on an opposite side of the first pixel defining film.

According to various embodiments of the present disclosure, the first pixel defining film may comprise a first side surface, a second side surface located further away from a center of an emission area than the first side surface, and a third side surface located closer to the center of the emission area than the first side surface, wherein the first side surface of the first pixel defining film and the bottom surface of the second sub-electrode may comprise the first undercut structure, and the third side surface of the first pixel defining film and the bottom surface of the second sub-electrode may comprise the second undercut structure.

According to various embodiments of the present disclosure, an electronic device comprises one or more processors providing an image signal, a display module receiving the image signal from the processor and displaying an image, and a power module supplying power to the display module, wherein the display module comprises a first electrode including a first sub-electrode and a second sub-electrode located on the first sub-electrode, a light emitting stack located on the first electrode, a second electrode located on the light emitting stack, and a first residual film located between the first sub-electrode and the second sub-electrode.

According to various embodiments of the present disclosure, at least a part of a bottom surface of the second sub-electrode may be exposed by the first residual film.

An electronic device comprises a processor providing an image signal, a display module receiving the image signal from the processor and displaying an image, and a power module supplying power to the display module, wherein the display module comprises a first electrode including a first sub-electrode and a second sub-electrode located on the first sub-electrode, a light emitting stack located on the first electrode, a second electrode located on the light emitting stack, and a first pixel defining film located between the first sub-electrode and the second sub-electrode, wherein at least a part of a bottom surface of the second sub-electrode may be located to be in contact with the first pixel defining film.

According to various embodiments of the present disclosure, at least a part of a bottom surface of the second sub-electrode may be exposed by the first pixel defining film.

According to the present disclosure, the display device may have an advantage of reducing the number of manufacturing processes of the display device by forming a first undercut structure by utilizing components that have been arranged in the related art.

According to the present disclosure, the probability of disconnection of a light emitting stack of the display device may be improved. Accordingly, the probability of current leakage may be reduced, and the luminous efficiency may be further increased.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail exemplary embodiments thereof with reference to the attached drawings, in which.

FIG. 1 is an exploded perspective view showing a display device according to an embodiment of the present disclosure.

FIG. 2 is a block diagram showing a display device according to an embodiment of the present disclosure.

FIG. 3 is an equivalent circuit diagram of a first sub-pixel according to an embodiment of the present disclosure.

FIG. 4 is a layout diagram illustrating an example of a display panel according to an embodiment of the present disclosure.

FIG. 5 is a layout diagram showing an example of the display area of FIG. 4.

FIG. 6 is a layout diagram showing an example of the display area of FIG. 4.

FIG. 7 is a cross-sectional view illustrating an example of a display panel taken along line I1-I1′ of FIG. 5.

FIG. 8 is a cross-sectional view illustrating an example of a display panel taken along line I1-I1′ of FIG. 5.

FIG. 9 is a diagram specifically showing a connection electrode, a reflective electrode, a first electrode, a light emitting stack, and a second electrode in a first sub-pixel, a second pixel, and a third sub-pixel of FIG. 8.

FIG. 10 is a partially enlarged view showing a first embodiment of the present disclosure.

FIG. 11 is a partially enlarged view showing a first modified example of the first embodiment of the present disclosure.

FIGS. 12 and 13 are partially enlarged view showing a second modified example of the first embodiment of the present disclosure.

FIG. 14 is a partially enlarged view showing a third modified example of the first embodiment of the present disclosure.

FIG. 15 is a partially enlarged view showing a second embodiment of the present disclosure.

FIG. 16 is a partially enlarged view showing a first modified example of the second embodiment of the present disclosure.

FIG. 17 is a partially enlarged view showing a third embodiment of the present disclosure.

FIG. 18 is a partially enlarged view showing a fourth embodiment of the present disclosure.

FIGS. 19 to 27 are cross-sectional views illustrating a common method of manufacturing a display device according to an embodiment of the present disclosure.

FIGS. 28 to 30 are cross-sectional views illustrating a method of manufacturing the display device according to the first embodiment.

FIGS. 31 to 33 are cross-sectional views illustrating a method of manufacturing the display device according to the second embodiment.

FIGS. 34 and 35 are cross-sectional views illustrating a method of manufacturing the display device according to the third embodiment and the fourth embodiment.

FIG. 36 is a perspective view illustrating a head mounted display according to an embodiment of the present disclosure.

FIG. 37 is an exploded perspective view illustrating an example of the head mounted display of FIG. 36.

FIG. 38 is a perspective view illustrating a head mounted display according to an embodiment of the present disclosure.

FIG. 39 is a block diagram of an electronic device according to an embodiment of the present disclosure.

FIG. 40 is schematic views of electronic devices according to various embodiments of the present disclosure.

### DETAILED DESCRIPTION OF THE EMBODIMENTS

The advantages and features of the embodiments disclosed herein, and methods of achieving them, will become apparent upon reference to the embodiments described in detail with accompanying drawings. However, aspects of the present disclosure are not limited to the embodiments disclosed herein, but will be embodied in many different forms, and these embodiments are provided merely to make the disclosure complete and to fully inform one of ordinary skill in the art to which the present disclosure belongs, and the present disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are exemplary and are not intended to be limiting to those shown herein.

Although first, second, and the like are used to describe various components, the components are not limited by these terms. Thus, a first component referred to herein may also be a second component within the technical idea of the present disclosure.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

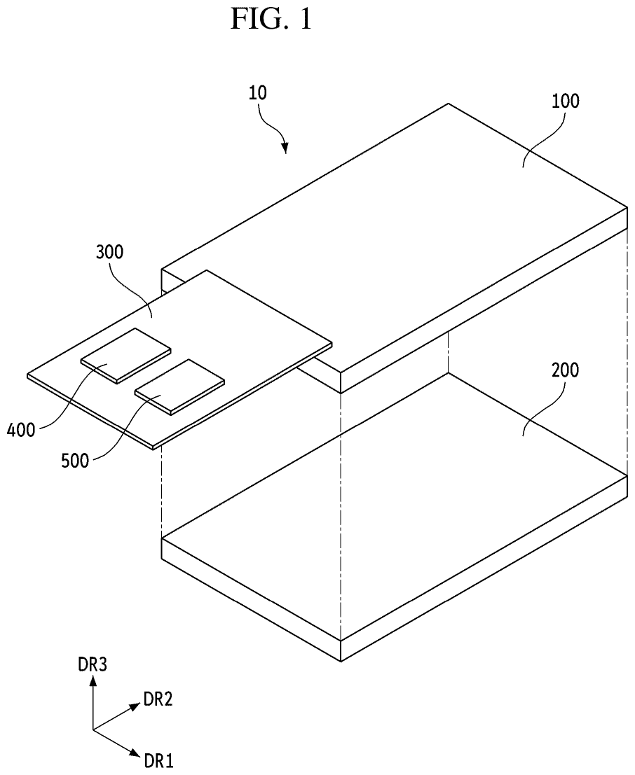

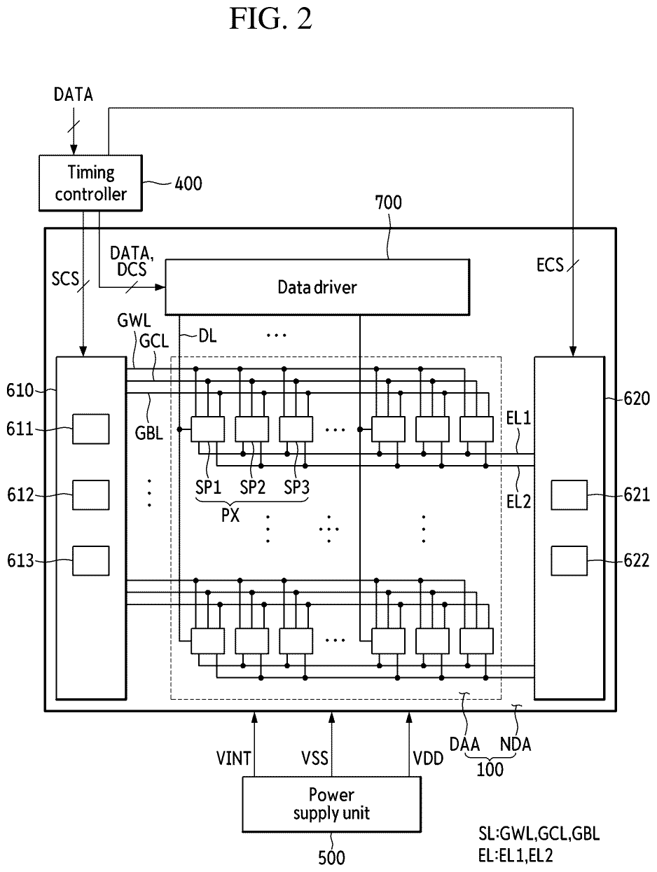

FIG. 1 is an exploded perspective view showing a display device according to an embodiment of the present disclosure. FIG. 2 is a block diagram showing a display device according to an embodiment of the present disclosure.

Referring to FIGS. 1 and 2, a display device 10 according to an embodiment is a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. In an example, the display device 10 according to an embodiment may be applied to a smart watch, a watch phone, a head mounted display (HMD) for implementing virtual reality and augmented reality, and the like.

The display device 10 according to an embodiment includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

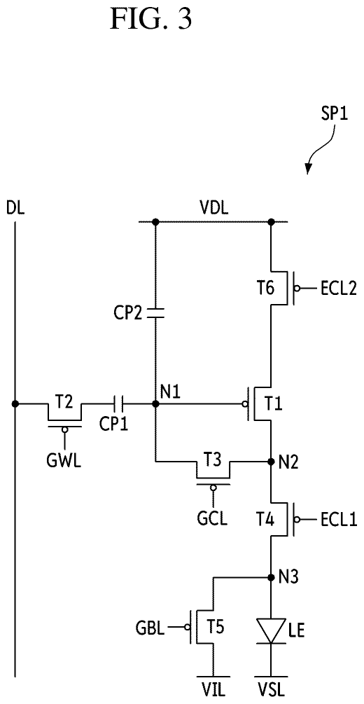

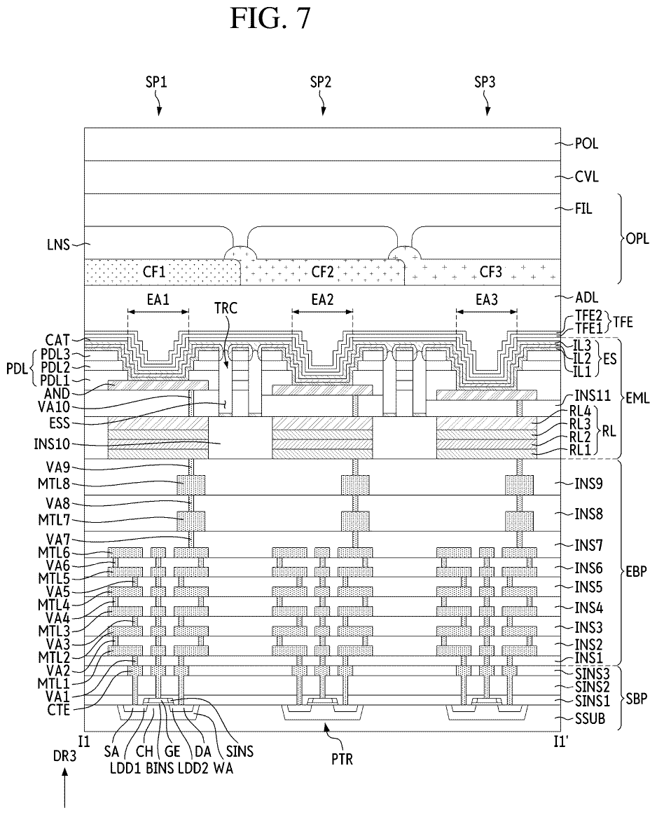

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and located on a semiconductor substrate SSUB (see FIG. 7). For example, the plurality of pixel transistors of the data driver 700 may be formed as complementary metal oxide semiconductor (CMOS) transistors, but the embodiment of the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be located in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed as CMOS transistors, but the embodiment of the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed as CMOS transistors, but the embodiment of the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface, e.g., the rear surface, of the display panel 100. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

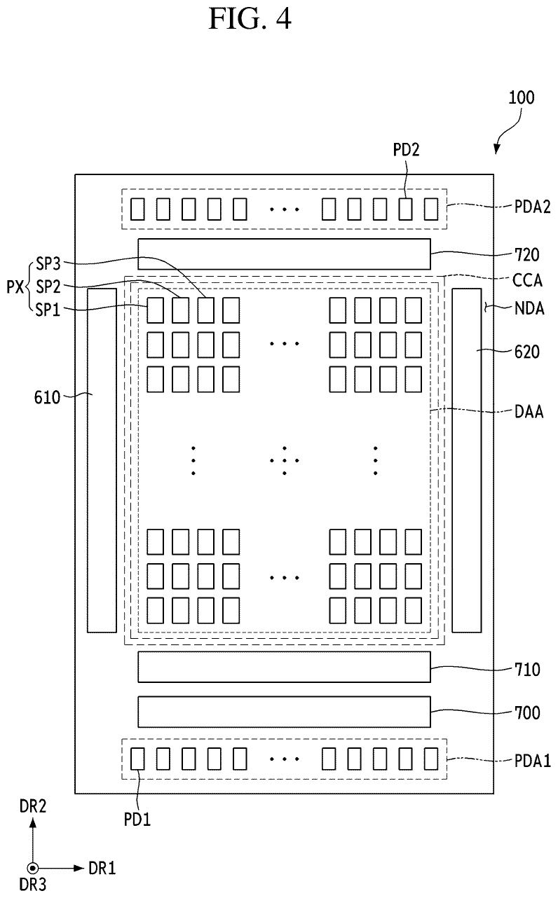

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals as input from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

For example, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed as CMOS transistors, but the embodiment of the present disclosure is not limited thereto. Each of the timing control circuit 400 and the power supply circuit 500 may be located between the data driver 700 and the first pad portion PDA1 (see FIG. 4).

FIG. 3 is an equivalent circuit diagram of a first sub-pixel according to an embodiment of the present disclosure.

Referring to FIG. 3, a first sub-pixel SP1 may be connected to the write scan line GWL, the control scan line GCL, the bias scan line GBL, the first emission control line ECL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer located between the first electrode and the second electrode, but the embodiment of the present disclosure is not limited thereto. For example, the light emitting element LE may be an inorganic light emitting element including a first electrode, a second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode according to a voltage applied to the gate electrode.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a p-type MOSFET, but the embodiment of the present disclosure is not limited thereto. Each of the first to sixth transistors T1 to T6 may be an n-type MOSFET. In other embodiments, one or more of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to an embodiment of the present disclosure.

Referring to FIG. 4, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, the embodiment of the present disclosure is not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

A cathode connection portion CCA may be a region in which a second electrode CAT (see FIG. 7) of a display element layer EML (see FIG. 7) is connected to the first driving voltage line VSL of the non-display area NDA. The cathode connection portion CCA may be located outside at least one side of the display area DAA. For example, the cathode connection portion CCA may be located outside at least on one side among the left side, the right side, the upper side, and the lower side of the display area DAA. In other embodiments, the cathode connection portion CCA may be located to surround the display area DAA as shown in FIG. 4 in order to minimize a deviation in the first driving voltage VSS due to a voltage drop (IR drop) or voltage rise (IR rising) of the second electrode CAT in the display area DAA.

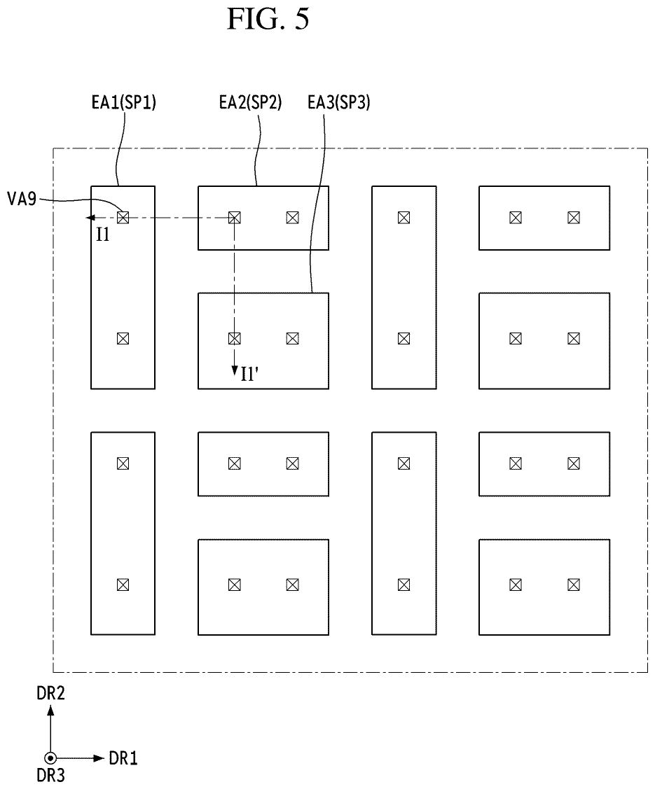

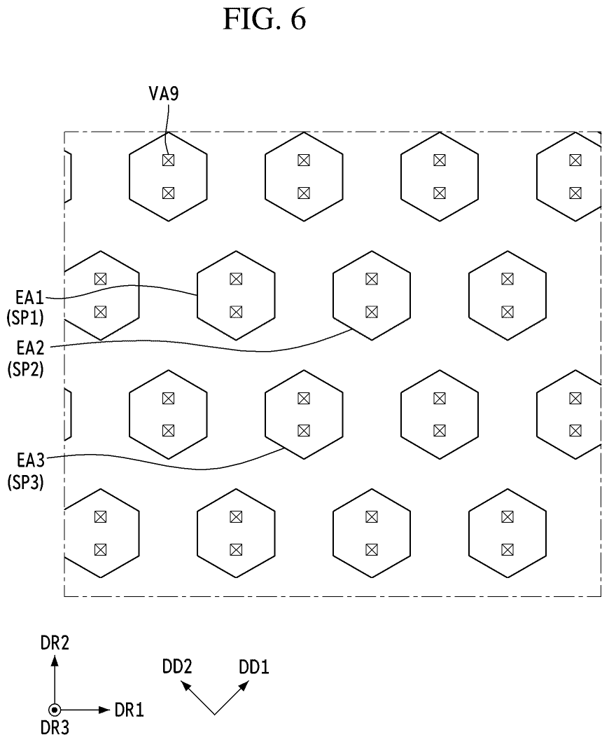

FIG. 5 is a layout diagram showing an example of the display area of FIG. 4. FIG. 6 is a layout diagram showing an example of the display area of FIG. 4.

Referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 5 and 6, but the present disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

In the example shown in FIG. 6, the emission areas EA1, EA2, EA3, and EA4 may have a hexagonal shape in a plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6.

FIG. 7 is a cross-sectional view illustrating an example of a display panel taken along line I1-I1′ of FIG. 5.

Referring to FIG. 7, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. In a different example, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include silicon carbonitride (SiCN) or a silicon oxide (SiOₓ)-based inorganic film, but the present disclosure is not limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers MTL1 to MTL8, a plurality of vias VA1 to VA9, and a plurality of insulating films INS1 to INS11. In addition, the light emitting element backplane EBP includes a plurality of insulating films INS1 to INS9 located between the first to eighth conductive layers MTL1 to MTL8.

The first to eighth insulating films INS1 to INS8 serve to insulate the first to eighth conductive layers MTL1 to MTL8. The first to eighth conductive layers MTL1 to MTL8 serve to connect the plurality of contact terminals CTE exposed from the semiconductor backplane SBP to thereby implement the circuit of the first sub-pixel SP1 shown in FIG. 3.

For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers MTL1 to MTL8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers MTL1 to MTL8.

The first to eighth conductive layers MTL1 to MTL8 and the first to eighth vias VA1 to VA8 may include substantially the same material. The first to eighth conductive layers MTL1 to MTL8 and the first to eighth vias VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include substantially the same material. The first to eighth insulating films INS1 to INS8 may be formed as silicon oxide (SiOₓ)-based inorganic films, but the embodiment of the present disclosure is not limited thereto.

A ninth insulating film INS9 may be located on the eighth insulating film INS8 and the eighth conductive layer MTL8. The ninth insulating film INS9 may be formed as a silicon oxide (SiOₓ)-based inorganic film, but the embodiment of the present disclosure is not limited thereto.

Each of the ninth vias VA9 may penetrate the ninth insulating film INS9 and be connected to the exposed eighth conductive layer MTL8. The ninth vias VA9 may include any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be located on the light emitting element backplane EBP. The display element layer EML may include tenth and eleventh insulating films INS10 and INS11, a reflective electrode RL, the first electrodes AND, a light emitting stack IL, the second electrode CAT, a pixel defining film PDL, and a plurality of trenches TRC.

The reflective electrode RL may be located on the ninth insulating film INS9. The reflective electrode RL may include at least one reflective electrode RL1, RL2, RL3, and RL4. For example, the reflective electrode RL may include the first to fourth reflective electrodes RL1, RL2, RL3, and RL4 as shown in FIG. 7. The reflective electrode RL may be formed in a tapered shape.

The first reflective electrodes RL1 may be located on the ninth interlayer insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be located on the ninth interlayer insulating film INS9. The tenth interlayer insulating film INS10 may be located between the reflective electrodes RL adjacent to each other. The tenth interlayer insulating film INS10 may be a film for flattening a stepped portion caused by the reflective electrodes RL. The eleventh interlayer insulating film INS11 may be located on the tenth interlayer insulating film INS10 and a reflective electrode layer RL.

The tenth interlayer insulating film INS10 and the eleventh interlayer insulating film INS11 may be formed as silicon oxide (SiOₓ)-based inorganic films, but the embodiment of the present disclosure is not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode layer RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as shown in FIG. 7, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode layer RL in the first sub-pixel SP1 is greater than the distance between the first electrode AND and the reflective electrode layer RL in the second sub-pixel SP2. In addition, the distance between the first electrode AND and the reflective electrode layer RL in the second sub-pixel SP2 is greater than the distance between the first electrode AND and the reflective electrode layer RL in the third sub-pixel SP3.

Each of the tenth vias VA10 may penetrate the eleventh interlayer insulating film INS11 and be connected to the exposed ninth metal layer ML9. The tenth vias VA10 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be located on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers MTL1 to MTL8, and the contact terminal CTE. The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE includes the first electrode AND, the light emitting stack IL, and the second electrode CAT is located.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed as silicon oxide (SiOₓ)-based inorganic films. In an example, the first pixel defining film PDL1 and the third pixel defining film PDL3 may be formed as silicon nitride (SiNₓ)-based inorganic films, whereas the second pixel defining film PDL2 may be formed as a silicon oxide (SiOₓ)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be at least partially recessed at each of the plurality of trenches TRC.

At least one trench TRC may be located between the neighboring sub-pixels SP1, SP2, and SP3. Although FIG. 7 illustrates that two trenches TRC are located between the neighboring sub-pixels SP1, SP2, and SP3, the present disclosure is not limited thereto.

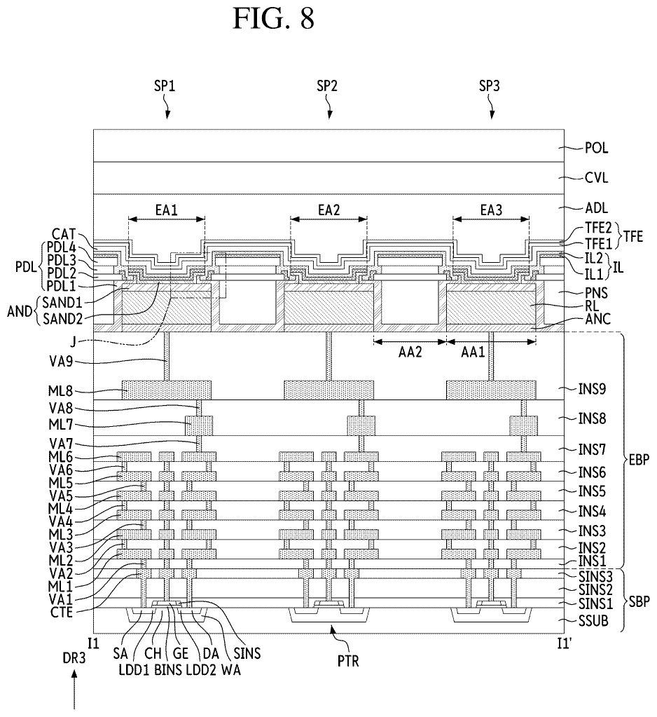

The light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but the present disclosure is not limited thereto. For example, the light emitting stack IL may have a two-tandem structure including two stack layers as shown in FIG. 8.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND and the pixel defining film PDL, and a residual film RIL located on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. A cavity ESS or an empty space may be located between the residual film RIL and the second stack layer IL2 in the trench TRC. The third stack layer IL3 may be located on the second stack layer IL2. The third stack layer IL3 is not cut off by the trench TRC and may be located to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer located between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be located on the pixel defining film PDL.

In addition, FIG. 7 illustrates that the light emitting stack IL that emits light is located in the first emission area EA1, the second emission area EA2, and the third emission area EA3, but the present disclosure is not limited thereto. For example, instead of the light emitting stack IL, the first light emitting layer may be located in the first emission area EA1, and may be omitted from the second emission area EA2 and the third emission area EA3. Furthermore, the second light emitting layer may be located in the second emission area EA2 and may be omitted from the first emission area EA1 and the third emission area EA3. Furthermore, the third light emitting layer may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the light emitting stack IL. The second electrode CAT may be located on the third stack layer IL3 in each of the plurality of trenches TRC. The second electrode CAT may include a transparent conductive material (TCO) such as ITO or IZO that can transmit light or a semi-transmissive conductive material such as magnesium (Mg), silver (Ag), or an alloy of Mg and Ag. When the second electrode CAT includes a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE2 to reduce or prevent oxygen or moisture from permeating into the display element layer EML. The first encapsulation inorganic film TFE1 may be located on the second electrode CAT, and the second encapsulation inorganic film TFE2 may be located on the first encapsulation inorganic film TFE1. The first encapsulation inorganic film TFE1 and the second encapsulation inorganic film TFE3 may be formed as multiple films in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In addition, the encapsulation layer TFE may include at least one organic film to protect the display element layer EML from foreign substances such as dust. The at least one organic film of the encapsulation layer TFE may be located between the first encapsulation inorganic film TFE1 and the second encapsulation inorganic film TFE2. The at least one organic film of the encapsulation layer TFE may be a monomer. In other embodiments, at least one organic film of the encapsulation layer TFE may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be located on the plurality of lenses LNS. The filling layer FIL may have a selected refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but the embodiment of the present disclosure is not limited thereto. However, when visibility degradation caused by reflection of external light is sufficiently overcome by the first to third color filters CF1, CF2, and CF3, the polarizing plate may be omitted.

FIG. 8 is a cross-sectional view illustrating still an example of a display panel taken along line I1-I1′ of FIG. 5.

The embodiment of FIG. 8 differs from the embodiment of FIG. 7 in that the first electrode AND of each of the light emitting elements LE is in contact with and electrically connected to the side surface of a connection electrode ANC connected to the eighth conductive layer ML8. The embodiment of FIG. 8 also differs from the embodiment of FIG. 7 in that the trench TRC is omitted, and instead, the third pixel defining film PDL3 and a fourth pixel defining film PDL4 may have an eaves-shaped or mushroom-shaped cross-sectional structure. In the embodiment of FIG. 8, redundant description of parts already described in the embodiment of FIG. 7 will be omitted.

Referring to FIG. 8, the plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. A plurality of connection electrodes ANC may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ)-based inorganic films, but the present disclosure is not limited thereto.

In each of the first emission area EA1 and the third emission area EA3, a step layer STPL may be located on the reflective electrode RL, and the optical auxiliary film OAL may be located on the step layer STPL. In the second emission area EA2, only the optical auxiliary film OAL may be located on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light emitting stack IL, and the wavelength and resonance distance of light emitted from the second stack layer IL2.

In the display device according to the embodiment of the present disclosure, the thickness of the step layer STPL may be the same in all of the first emission area EA1, the second emission area EA2, and the third emission area EA3. The thicknesses of the components located inside the light emitting stacks IL1 and IL2 may be adjusted by considering the wavelength and resonance distance of the light emitted from each emission area. This will be described in detail later.

Each of the light emitting elements LE may include the first electrode AND, a light emitting stack IL, and a second electrode CAT.

The first electrode AND of each of the light emitting elements LE may be located on the optical auxiliary film OAL corresponding thereto. Since the connection electrode ANC, the reflective electrode RL, and the optical auxiliary layer film are sequentially stacked, the first electrode AND of each of the light emitting elements LE may be located on the top surface and the side surface of the optical auxiliary film OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to when the first electrode AND of each of the light emitting elements LE is connected to the reflective electrode RL exposed through a through hole penetrating the optical auxiliary film OAL, the number of mask processes may be reduced, thereby advantageously lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers MTL1 to MTL8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth insulating film INS9 may be substantially the same.

In an example, the thickness of the first portion AA1 of the ninth insulating film INS9 may be greater than the thickness of the second portion AA2. In this case, the side surface of the first portion AA1 of the ninth insulating film INS9 may be exposed, and the first electrode AND of each of the light emitting elements LE may be located on the exposed side surface of the first portion AA1 of the ninth insulating film INS9.

The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but the embodiment of the present disclosure is limited thereto.

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be located on the first electrode AND of each of the light emitting elements LE. Specifically, the first pixel defining film PDL1 may cover a part of the top surface of the first electrode AND located on the optical auxiliary film OAL. Further, the first pixel defining film PDL1 may cover the first electrode AND located on the side surface of the connection electrode ANC, the side surface of the reflective electrode RL, and the side surface of the optical auxiliary film OAL. The first pixel defining film PDL1 may be located on the top surface of the second portion AA2 of the ninth insulating film INS9.

A planarization film PNS is a film for flattening the stepped portion caused by the connection electrode ANC, the reflective electrode RL, and the optical auxiliary film OAL.

The planarization film PNS may be located on the first pixel defining film PDL1 covering the first electrode AND located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth insulating film INS9.

The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 located on the top surface of the first electrode AND located in the second emission area EA2.

In contrast, the top surface of the planarization film PNS may be flatly connected to the top surface of the first pixel defining film PDL1 located on the top surface of the first electrode AND located in the first emission area EA1 and the third emission area EA3. That is, the planarization film PNS may not cover the top surface of the first pixel defining film PDL1 located on the top surface of the first electrode AND located in each of the first emission area EA1 and the third emission area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 may be formed as silicon nitride (SiNₓ)-based inorganic films, whereas the second pixel defining film PDL2, the fourth pixel defining film PDL4, and the planarization film PNS may be formed as silicon oxide (SiOₓ)-based inorganic films. The first pixel defining film PDL1 includes a material different from that of the planarization film PNS, and thus may serve as a stopper in a chemical mechanical polishing process for the planarization film PNS.

When the planarization film PNS and the second pixel defining film PDL2 are both formed as silicon oxide (SiOₓ)-based inorganic films, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. In other words, the third pixel defining film PDL3 and the fourth pixel defining film PDL4 may have an eave-shaped or mushroom-shaped cross-sectional structure.

The light emitting stack IL may be located on the first electrode AND and the pixel defining film PDL. The light emitting stack IL may include the first stack layer IL1 and the second stack layer IL2 that are configured to emit different lights. When the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be located between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer located between the first stack layer IL1 and the second stack layer IL2 may also be cut off. Further, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to prevent the light emitting stack IL in the adjacent emission areas EA1, EA2, and EA3 from emitting light other than the originally intended light due to the influence of the above current.

In an embodiment, the first stack layer IL1 may also be cut at one end and/or the other end of a second sub-electrode SAND2. The first electrode AND may include a first sub-electrode SAND1 and the second sub-electrode SAND2. An undercut-shaped structure may be formed at one end and/or the other end of the second sub-electrode SAND2. An undercut-shaped structure may be formed by the first sub-electrode SAND1 and the first pixel defining film PDL1. This will be described in detail later.

Although FIG. 8 illustrates a two-tandem structure in which the light emitting stack IL includes two stack layers IL1 and IL2, the present disclosure is not limited thereto. For example, the light emitting stack IL may have a three-tandem structure including three stack layers as shown in FIG. 7. In this case, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. In an embodiment shown in FIG. 7, the trench TRC penetrating the first pixel defining film PDL1, the second pixel defining film PDL2, and the third pixel defining film PDL3 may be added. In this case, the trench TRC may penetrate at least a part of the ninth insulating film INS9, but the present disclosure is not limited thereto.

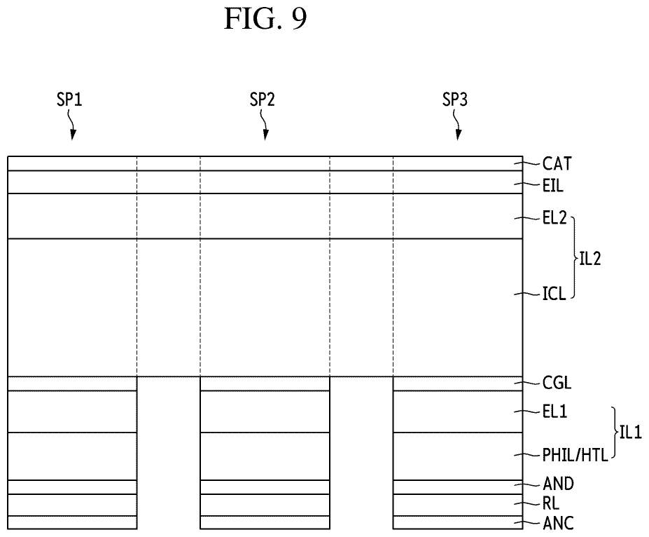

FIG. 9 is a diagram specifically showing a connection electrode, a reflective electrode, a first electrode, a light emitting stack, and a second electrode in a first sub-pixel, a second pixel, and a third sub-pixel of FIG. 8.

Referring to FIG. 9, in a two-tandem structure, the light emitting stacks IL1 and IL2 may include the plurality of stack layers IL1 and IL2 that emit different lights. For example, the light emitting stack IL1 and IL2 may include the first stack layer IL1 that emits first light and the second stack layer IL2 that emits second light.

In a three-tandem structure, the light emitting stack may include a plurality of stack layers that emit different lights. The light emitting stack may further include a third stack layer that emits the third light.

The first stack layer IL1 and the second stack layer IL2 may be stacked sequentially. A charge generation layer CGL may be located between the plurality of stack layers IL1 and IL2. For example, the charge generation layer CGL may be located between the first stack layer IL1 and the second stack layer IL2.

The first stack layer IL1 may include a hole transport layer HTL or a hole injection layer PHIL, and a first organic light emitting stack EL1 that emits the first light. These may be stacked sequentially.

The second stack layer IL2 may include an interconnection layer ICL and a second organic light emitting stack EL2 that emits the second light. These may be stacked sequentially. The interconnection layer ICL may include at least one of a hole transport layer or a hole injection layer.

A charge generation layer CGL for supplying holes to the second stack layer IL2 and supplying electrons to the first stack layer IL1 may be located between the first stack layer IL1 and the second stack layer IL2. The charge generation layer CGL may include an n-type charge generation layer that supplies electrons to the first stack layer IL1. The charge generation layer CGL may include a p-type charge generation layer that supplies holes to the second stack layer IL2. The n-type charge generation layer may include a dopant of a metal material.

A third stack layer may be located between the second stack layer IL2 and an electron injection layer EIL. When the third stack layer is located, a second charge generation layer may be located between the third stack layer and the second stack layer IL2. The second charge generation layer may include an n-type charge generation layer that supplies electrons to the second stack layer IL2. The second charge generation layer may include a p-type charge generation layer that supplies holes to the third stack layer. The n-type charge generation layer may include a dopant of a metal material.

The third stack layer may include a second interconnection layer and a third organic light emitting stack that emits the third light. These may be stacked sequentially. The second interconnection layer may include at least one of a hole transport layer or a hole injection layer. To apply a micro-cavity effect, the thickness of the second interconnection layer may be greater than the thickness of the interconnection layer ICL. However, the embodiments of the present disclosure are not limited thereto. The thickness of the interconnection layer ICL and the thickness of the second interconnection layer may be set in consideration of the main peak wavelength of the first light, the main peak wavelength of the second light, the main peak wavelength of the third light, the distance between the first organic light emitting stack EL1 and the reflective electrode RL, the distance between the first organic light emitting stack EL1 and the second electrode CAT, the distance between the second organic light emitting stack EL2 and the reflective electrode RL, the distance between the second organic light emitting stack EL2 and the second electrode CAT, the distance between the third organic light emitting stack EL3 and the reflective electrode RL, the distance between the third organic light emitting stack EL3 and the second electrode CAT, the distance between the reflective electrode RL and the second electrode CAT, and so forth. In some embodiments, a separate step layer may not be required to apply a micro-cavity effect. Accordingly, the number of masks for forming the step layer by the photolithography process may be reduced, and the manufacturing cost of the display device may be reduced.

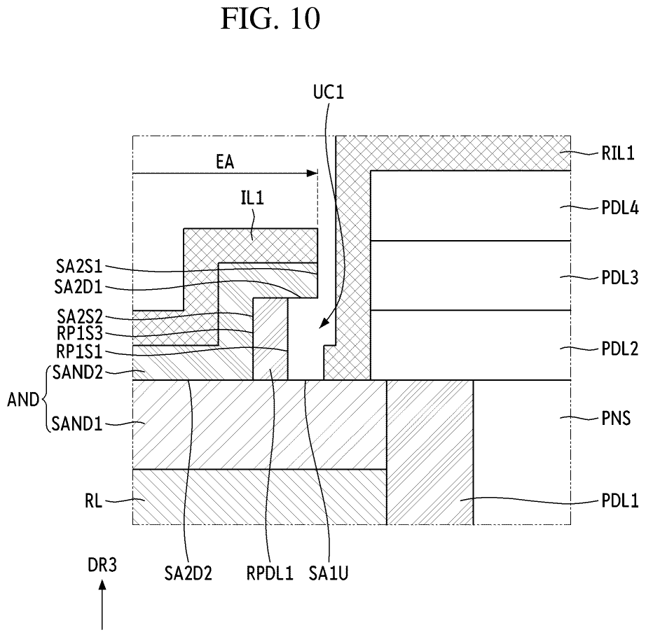

FIGS. 10 to 18 are various partially enlarged views illustrating part J of FIG. 8 in an enlarged manner. Hereinafter, embodiments and modified examples illustrated in various partially enlarged views are described.

FIG. 10 is a partially enlarged view showing a first embodiment of the present disclosure.

Referring to FIG. 10, the display device according to the first embodiment includes the reflective electrode RL, the first electrode AND located on the reflective electrode RL, and the first stack layer IL1 located on the first electrode AND. The first electrode AND may include a first sub-electrode SAND1 and the second sub-electrode SAND2. The first sub-electrode SAND1 may include a material different from that of the second sub-electrode SAND2. For example, the first sub-electrode SAND1 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first sub-electrode SAND1 may be titanium nitride (TiN). The second sub-electrode SAND2 may include a transparent conductive material (TCO) such as ITO or IZO that can transmit light or a semi-transmissive conductive material such as magnesium (Mg), silver (Ag), or an alloy of Mg and Ag. The second sub-electrode SAND2 may be indium tin oxide (ITO).

The first pixel defining film PDL1 may be located on one side surface of the reflective electrode RL and one side surface of the first sub-electrode SAND1. The planarization film PNS may be located on one side surface of the first pixel defining film PDL1. The second pixel defining film PDL2, the third pixel defining film PDL3, and the fourth pixel defining film PDL4 may be located on the first pixel defining film PDL1 and the planarization film PNS. These may be formed to cover the edge of the first sub-electrode SAND1. The second pixel defining film PDL2, the third pixel defining film PDL3, or the fourth pixel defining film PDL4 may be omitted.

A light emitting stack residual film RIL1 may be located on the second pixel defining film PDL2, the third pixel defining film PDL3, and the fourth pixel defining film PDL4. The light emitting stack residual film RIL1 may be formed to cover all of the top surface of the fourth pixel defining film PDL4 and the side surfaces of the second pixel defining film PDL2, the third pixel defining film PDL3, and the fourth pixel defining film PDL4. The light emitting stack residual film RIL1 may be derived from the first stack layer IL1. The light emitting stack residual film RIL1 may include the same material as the first stack layer IL1.

The first pixel defining film PDL1 may be located between the side surface of the first sub-electrode SAND1 and the planarization film PNS. A residual pixel defining film RPDL1 (or a first residual film) may be located on the first sub-electrode SAND1. The shape or the like of the residual pixel defining film RPDL1 is not limited to that illustrated, as described below. The residual pixel defining film RPDL1 may be derived from the first pixel defining film PDL1. The residual pixel defining film RPDL1 may include the same material as the first pixel defining film PDL1.

A second side surface SA2S2 of the second sub-electrode SAND2 may be located closer to the center of the emission area EA than a first side surface SA2S1 of the second sub-electrode SAND2. A first side surface RP1S1 of the residual pixel defining film RPDL1 may be located closer to the center of the emission area EA than the first side surface SA2S1 of the second sub-electrode SAND2, and the second side surface SA2S2 of the second sub-electrode SAND2 may be located closer to the center of the emission area EA than the first side surface RP1S1 of the residual pixel defining film RPDL1. The second side surface SA2S2 of the second sub-electrode SAND2 may be located to be in contact with a third side surface RP1S3 of the residual pixel defining film RPDL1. A first bottom surface SA2D1 of the second sub-electrode SAND2 may be located closer to the topmost surface of the first stack layer IL1 than a second bottom surface SA2D2 of the second sub-electrode SAND2.

The residual pixel defining film RPDL1 may be located between the first sub-electrode SAND1 and the second sub-electrode SAND2. The residual pixel defining film RPDL1 may be derived from the first pixel defining film PDL1 and thus may contain the same material as the first pixel defining film PDL1, but may be separated from the first pixel defining film PDL1. At this time, a top surface SA1U of the first sub-electrode SAND1 and the bottom surface of the second pixel defining film PDL2 may be located at substantially the same height.

At least a part of the first bottom surface SA2D1 of the second sub-electrode SAND2 may overlap the residual pixel defining film RPDL1 in the thickness direction. At least a part of the first bottom surface SA2D1 of the second sub-electrode SAND2 may be exposed without being covered by the residual pixel defining film RPDL1. In an embodiment, a first undercut structure UC1 may be located on one side of the residual pixel defining film RPDL1. The first undercut structure UC1 may be located between the first sub-electrode SAND1 and the second sub-electrode SAND2.

The first undercut structure UC1 may be formed by the first bottom surface SA2D1 of the second sub-electrode SAND2 on one side of the residual pixel defining film RPDL1 and one side surface of the residual pixel defining film RPDL1. The first undercut structure UC1 may be formed by the top surface SA1U of the first sub-electrode SAND1 and one side surface of the residual pixel defining film RPDL1.

The light emitting stack residual film RIL1 may be separated from the first stack layer IL1 by the first undercut structure UC1. Accordingly, the light emitting stack residual film RIL1 may include the same material as the first stack layer IL1. During the operation of the display device, light may be emitted from the first stack layer IL1, but no light may be emitted from the light emitting stack residual film RIL1.

In relation to the prior art, since the light emitting stack located on the pixel defining film is commonly deposited on the emission areas EA during the deposition process, a problem may occur in which carriers (electrons or holes) or the like move to the emission areas EA other than the intended emission area EA. In this way, when carriers move to other unintended emission areas EA and the designed current does not flow in the intended emission area EA, the luminous efficiency may decrease. To prevent such lateral leakage of current, an undercut structure may be formed in the pixel defining film. As described above, the undercut structure has been implemented in the second pixel defining film PDL2, the third pixel defining film PDL3, and the fourth pixel defining film PDL4 in the related art.

The display device according to the first embodiment of the present disclosure includes the residual pixel defining film RPDL1 including the same material as the first pixel defining film PDL1 but separated from the first pixel defining film PDL1. The residual pixel defining film RPDL1 may be located between the first sub-electrode SAND1 and the second sub-electrode SAND2 to form the first undercut structure UC1. The first undercut structure UC1 may replace the eaves-shaped or mushroom-shaped cross-sectional structure formed by the second pixel defining film PDL2, the third pixel defining film PDL3, and the fourth pixel defining film PDL4. In other embodiments, both undercut structures may be implemented, as in a first modified example of the first embodiment described below. The display device according to the embodiment of the present disclosure may form the residual pixel defining film RPDL1 by utilizing the first pixel defining film PDL1 and implement the first undercut structure UC1 by the residual pixel defining film RPDL1. Accordingly, there may be no need to deposit the second pixel defining film PDL2, the third pixel defining film PDL3, and the fourth pixel defining film PDL4 to implement a separate undercut structure. The display device may have an advantage of reducing the number of manufacturing processes of the display device since the first undercut structure UC1 is formed by utilizing the components that have been arranged in the related art.

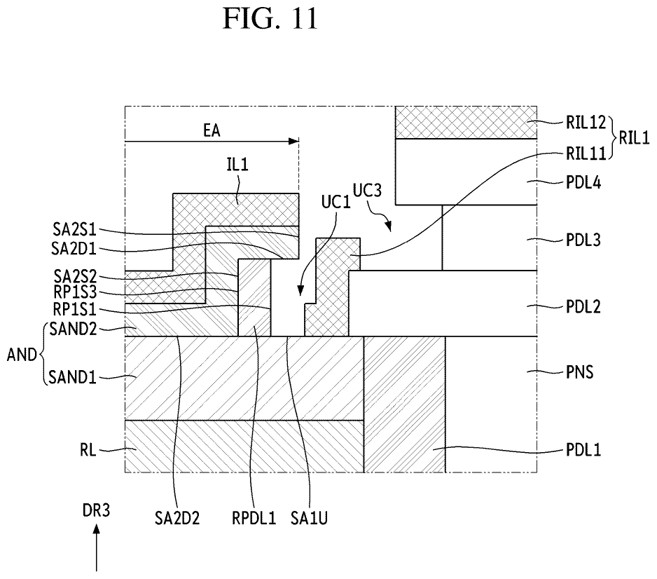

FIG. 11 is a partially enlarged view showing the first modified example of the first embodiment of the present disclosure.

Referring to FIG. 11, the first modified example of the first embodiment differs from the first embodiment in that it includes the second pixel defining film PDL2, the third pixel defining film PDL3, and the fourth pixel defining film PDL4 in an eaves shape or a mushroom shape. Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. In other words, the third pixel defining film PDL3 and the fourth pixel defining film PDL4 may have an eave-shaped or mushroom-shaped cross-sectional structure.

The embodiment may include a plurality of undercut structures. The plurality of undercut structures may include the first undercut structure UC1 implemented by the residual pixel defining film RPDL1 located between the first sub-electrode SAND1 and the second sub-electrode SAND2, and a third undercut structure UC3 implemented by the third pixel defining film PDL3 and the fourth pixel defining film PDL4.

The light emitting stack residual film RIL1 may be formed in plural number. For example, the light emitting stack residual film RIL1 may include a first light emitting stack residual film RIL11 formed by the first undercut structure UC1 and a second light emitting stack residual film RIL12 formed by the third undercut structure UC3.

The first modified example may improve the probability of disconnection of the light emitting stack of the display device. Accordingly, the probability of current leakage may be reduced, and the luminous efficiency may be further increased.

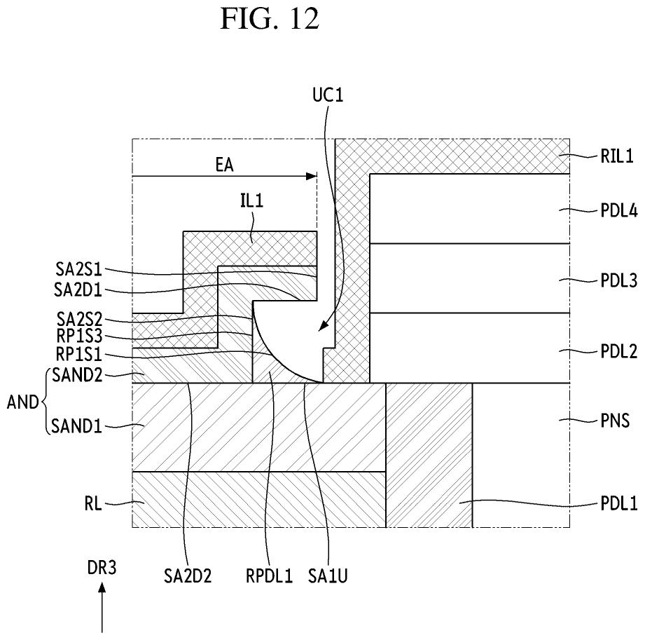

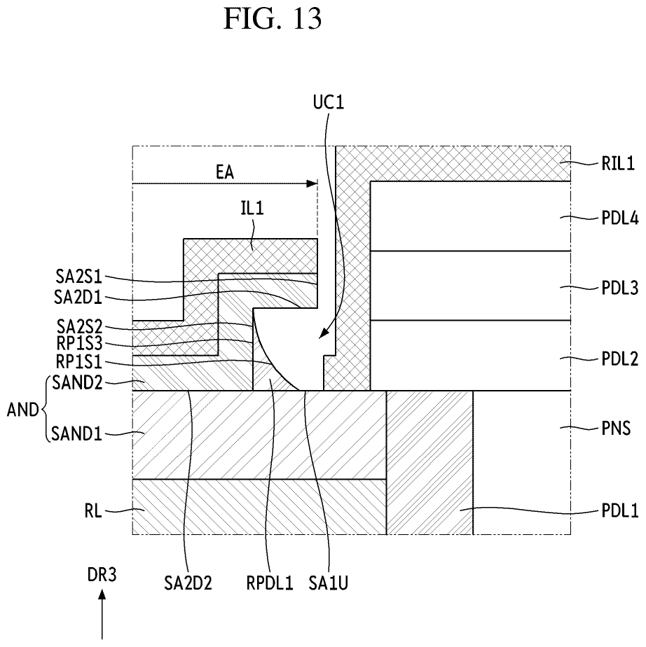

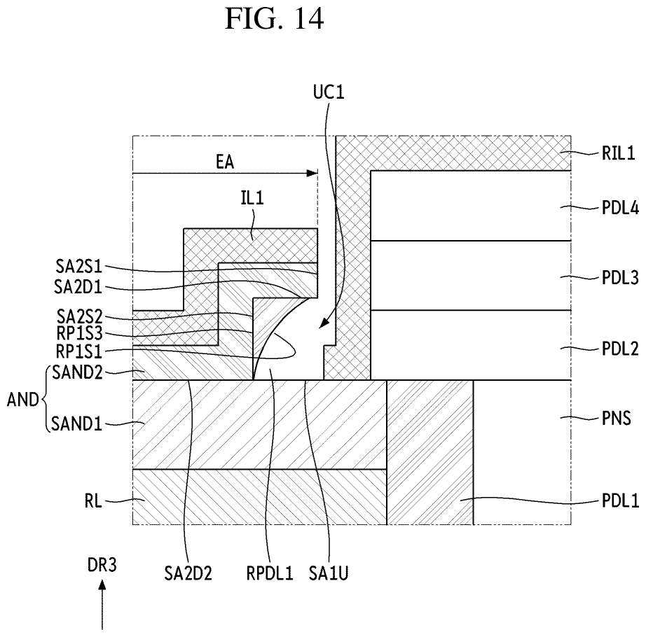

FIGS. 12 and 13 are partially enlarged view showing a second modified example of the first embodiment of the present disclosure. FIG. 14 is a partially enlarged view showing a third modified example of the first embodiment of the present disclosure.

Referring to FIG. 12, the first side surface RP1S1 of the residual pixel defining film RPDL1 may have a curvature. For example, the first side surface RP1S1 of the residual pixel defining film RPDL1 may be an isotropic etching surface formed by an etching process. The second side surface of the residual pixel defining film RPDL1 may be closer to the center of the emission area EA than the first side surface RP1S1 of the residual pixel defining film RPDL1. The first bottom surface SA2D1 of the second sub-electrode SAND2 and the first side surface RP1S1 of the residual pixel defining film RPDL1 may form the first undercut structure UC1.

Referring to FIG. 13, the residual pixel defining film RPDL1 may overlap at least a part of the top surface SA1U of the first sub-electrode SAND1. The overlapping area of the residual pixel defining film RPDL1 may vary depending on the process conditions performed in the etching process. Etching process conditions may include the type of etchant, dry/wet, temperature, humidity, process time, or the like.

Referring to FIG. 14, the first undercut structure UC1 may be formed by the first side surface RP1S1 of the residual pixel defining film RPDL1 and the top surface SA1U of the first sub-electrode SAND1. Compared to a second modified example, the direction of the curved surface formed by the isotropic etching surface may be different from that in a second embodiment and a third embodiment. For example, in the third modified example, the residual pixel defining film RPDL1 may be located between the first side surface RP1S1 of the residual pixel defining film RPDL1 and the first bottom surface SA2D1 of the second sub-electrode SAND2. In the second modified example, the residual pixel defining film RPDL1 may be located between the first side surface RP1S1 of the residual pixel defining film RPDL1 and the top surface SA1U of the first sub-electrode SAND1.

As in the first embodiment, the second modified example and the third modified example described above, the first side surface RP1S1 of the residual pixel defining film RPDL1 may be modified in various ways.

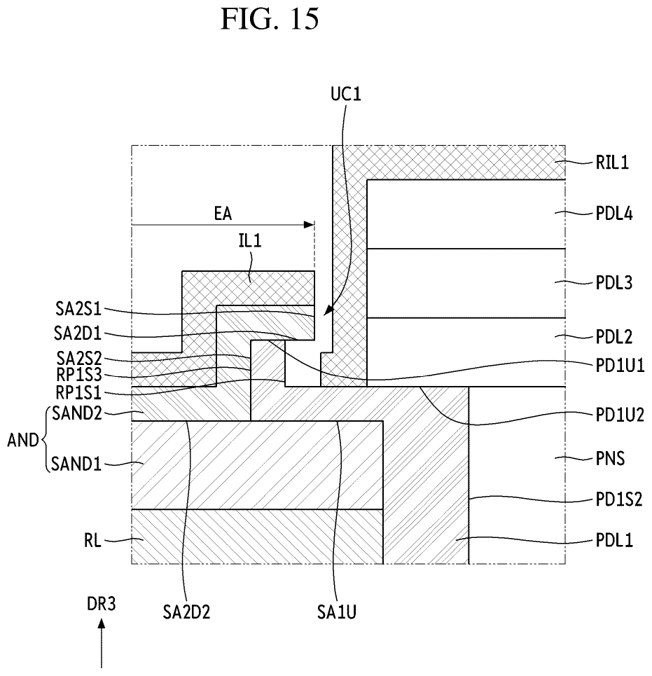

FIG. 15 is a partially enlarged view showing the second embodiment of the present disclosure.

Referring to FIG. 15, the display device according to the second embodiment includes the reflective electrode RL, the first electrode AND located on the reflective electrode RL, and the first stack layer IL1 located on the first electrode AND. The first electrode AND may include a first sub-electrode SAND1 and the second sub-electrode SAND2. The first sub-electrode SAND1 may include a material different from that of the second sub-electrode SAND2. For example, the first sub-electrode SAND1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first sub-electrode SAND1 may be titanium nitride (TiN). The second sub-electrode SAND2 may be formed of a transparent conductive material (TCO) such as ITO or IZO that can transmit light or a semi-transmissive conductive material such as magnesium (Mg), silver (Ag), or an alloy of Mg and Ag. The second sub-electrode SAND2 may be indium tin oxide (ITO).

The first pixel defining film PDL1 may be located on one side surface of the reflective electrode RL and one side surface of the first sub-electrode SAND1. The planarization film PNS may be located on one side surface PD1S2 of the first pixel defining film PDL1. The second pixel defining film PDL2, the third pixel defining film PDL3, and the fourth pixel defining film PDL4 may be located on the first pixel defining film PDL1 and the planarization film PNS. The first pixel defining film PDL1, the second pixel defining film PDL2, the third pixel defining film PDL3, and the fourth pixel defining film PDL4 may be formed to cover the edge of the first sub-electrode SAND1. The second pixel defining film PDL2, the third pixel defining film PDL3, or the fourth pixel defining film PDL4 may be omitted.

The light emitting stack residual film RIL1 may be located on the second pixel defining film PDL2, the third pixel defining film PDL3, and the fourth pixel defining film PDL4. The light emitting stack residual film RIL1 may be formed to cover all of the top surface of the fourth pixel defining film PDL4 and the side surfaces of the second pixel defining film PDL2, the third pixel defining film PDL3, and the fourth pixel defining film PDL4. The light emitting stack residual film RIL1 may be derived from the first stack layer IL1. The light emitting stack residual film RIL1 may include the same material as the first stack layer IL1.

At least a part of the pixel defining film PDL1 may be located between the side surface of the first sub-electrode SAND1 and the planarization film PNS. In a difference from the first embodiment, in the second embodiment, the first pixel defining film PDL1 may form the first undercut structure UC1.

The second side surface SA2S2 of the second sub-electrode SAND2 may be located closer to the center of the emission area EA than the first side surface SA2S1 of the second sub-electrode SAND2. The first side surface RP1S1 of the first pixel defining film PDL1 may be located closer to the center of the emission area EA than a second side surface PDLS2 of the first pixel defining film PDL1. The first side surface RP1S1 of the first pixel defining film PDL1 may be located between the second side surface PDLS2 of the first pixel defining film PDL1 and the third side surface RP1S3 of the first pixel defining film PDL1. The third side surface RP1S3 of the first pixel defining film PDL1 may be located closer to the center of the emission area EA than the first side surface RP1S1 of the first pixel defining film PDL1.

A first top surface PD1U1 of the first pixel defining film PDL1 may be located closer to the topmost surface of the second sub-electrode SAND2 than a second top surface PD1U2 of the first pixel defining film PDL1. The first side surface RP1S1 of the first pixel defining film PDL1 may be located closer to the center of the emission area EA than the first side surface SA2S1 of the second sub-electrode SAND2, and the second side surface SA2S2 of the second sub-electrode SAND2 may be located closer to the center of the emission area EA than the first side surface RP1S1 of the first pixel defining film PDL1. The second side surface SA2S2 of the second sub-electrode SAND2 may be located to be in contact with the third side surface RP1S3 of the first pixel defining film PDL1. The first bottom surface SA2D1 of the second sub-electrode SAND2 may be located closer to the topmost surface of the second sub-electrode SAND2 than the second bottom surface SA2D2 of the second sub-electrode SAND2.

At least a part of the first pixel defining film PDL1 may be located between the first sub-electrode SAND1 and the second sub-electrode SAND2. At this time, the top surface SA1U of the first sub-electrode SAND1 may be located at a lower height than the bottom surface of the second pixel defining film PDL2. The top surface SA1U of the first sub-electrode SAND1 and the bottom surface of the second pixel defining film PDL2 may have different heights.

At least a part of the first bottom surface SA2D1 of the second sub-electrode SAND2 may overlap the first top surface PD1U1 of the first pixel defining film PDL1 in the thickness direction. Only a part of the first bottom surface SA2D1 of the second sub-electrode SAND2 may be located to be in contact with the first top surface PD1U1 of the first pixel defining film PDL1 in the thickness direction.

At least a part of the first bottom surface SA2D1 of the second sub-electrode SAND2 may be exposed without being covered by the first top surface PD1U1 of the first pixel defining film PDL1. Specifically, only a part of the first bottom surface SA2D1 of the second sub-electrode SAND2 may be exposed without being covered by the first top surface PD1U1 of the first pixel defining film PDL1. In an embodiment, the first undercut structure UC1 may be located at the first side surface RP1S1 of the first pixel defining film PDL1. The first undercut structure UC1 may be located between the first sub-electrode SAND1 and the second sub-electrode SAND2.

The first undercut structure UC1 may be formed by the first bottom surface SA2D1 of the second sub-electrode SAND2 at the first side surface RP1S1 of the first pixel defining film PDL1 and the first side surface RP1S1 of the first pixel defining film PDL1. The first undercut structure UC1 may be formed by the second top surface PD1U2 of the first pixel defining film PDL1 and the first side surface RP1S1 of the first pixel defining film PDL1. The first undercut structure UC1 may be formed by the first bottom surface SA2D1 of the second sub-electrode SAND2, the second top surface PD1U2 of the first pixel defining film PDL1, and the first side surface RP1S1 of the first pixel defining film PDL1.

The light emitting stack residual film RIL1 may be separated from the first stack layer IL1 by the first undercut structure UC1. Accordingly, the light emitting stack residual film RIL1 may include the same material as the first stack layer IL1. During the operation of the display device, light may be emitted from the first stack layer IL1, but no light may be emitted from the light emitting stack residual film RIL1.

A display device according to the second embodiment of the present disclosure includes the first pixel defining film PDL1 including a plurality of bending portions. At least a part of the first pixel defining film PDL1 may be located between the first sub-electrode SAND1 and the second sub-electrode SAND2 to form the first undercut structure UC1. The first undercut structure UC1 may replace the eaves-shaped or mushroom-shaped cross-sectional structure formed by the second pixel defining film PDL2, the third pixel defining film PDL3, and the fourth pixel defining film PDL4. In other embodiments, both undercut structures may be implemented, as in a first modified example of the second embodiment described below. The display device according to the embodiment of the present disclosure may implement the first undercut structure UC1 by utilizing the first pixel defining film PDL1. Accordingly, there may be no need to deposit the second pixel defining film PDL2, the third pixel defining film PDL3, and the fourth pixel defining film PDL4 to implement a separate undercut structure. The display device may have an advantage of reducing the number of manufacturing processes of the display device since the first undercut structure UC1 is utilized by utilizing the components that have been arranged in the related art.

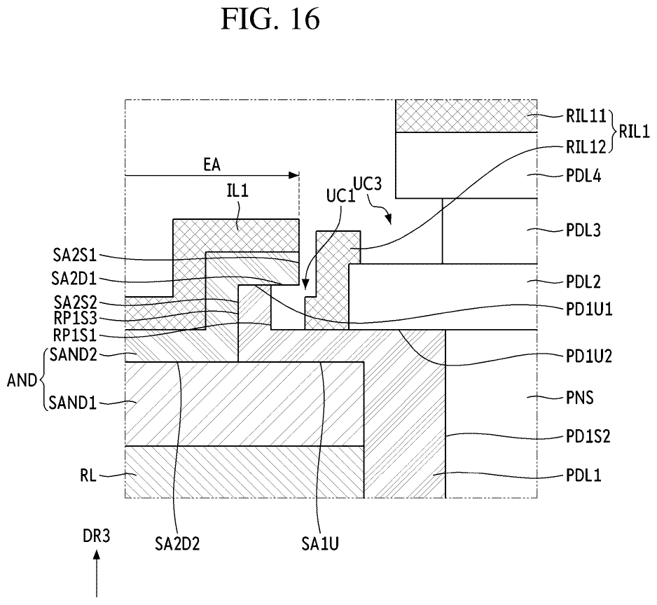

FIG. 16 is a partially enlarged view showing a first modified example of the second embodiment of the present disclosure.

Referring to FIG. 16, the first modified example of the second embodiment differs from the second embodiment in that it includes the second pixel defining film PDL2, the third pixel defining film PDL3, and the fourth pixel defining film PDL4 in an eaves shape or a mushroom shape. Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. In other words, the third pixel defining film PDL3 and the fourth pixel defining film PDL4 may have an eave-shaped or mushroom-shaped cross-sectional structure.

The embodiment may include a plurality of undercut structures UC1 and UC3. The plurality of undercut structures UC1 and UC3 may include the first undercut structure UC1 implemented by the residual pixel defining film RPDL1 located between the first sub-electrode SAND1 and the second sub-electrode SAND2, and a third undercut structure UC3 implemented by the third pixel defining film PDL3 and the fourth pixel defining film PDL4.

The light emitting stack residual film RIL1 may be formed in plural number. For example, the light emitting stack residual film RIL1 may include a first light emitting stack residual film RIL11 formed by the first undercut structure UC1 and a second light emitting stack residual film RIL12 formed by the third undercut structure UC3.

The first modified example may improve the probability of disconnection of the light emitting stack of the display device. Accordingly, the probability of current leakage may be reduced, and the luminous efficiency may be further increased.

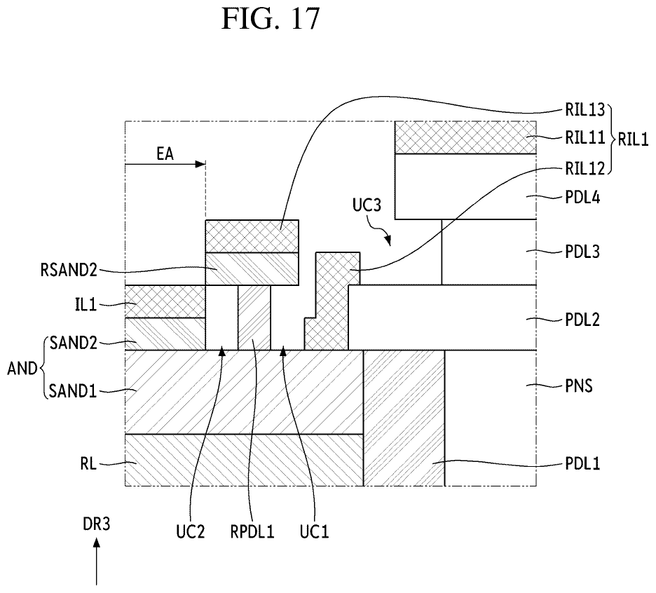

FIG. 17 is a partially enlarged view showing the third embodiment of the present disclosure.

Referring to FIG. 17, the third embodiment may include the first undercut structure UC1, a second undercut structure UC2, and the third undercut structure UC3. In the third embodiment, an undercut structure may be formed not only on one side but also on the other side of the residual pixel defining film in the first modified example of the first embodiment.

The third embodiment may include a residual second sub-electrode RSAND2 including the same material as the second sub-electrode SAND2. The residual second sub-electrode RSAND2 may be derived from the second sub-electrode SAND2.

The third embodiment may include the first light emitting stack residual film RIL11, the second light emitting stack residual film RIL12, and a third light emitting stack residual film RIL13 due to the first undercut structure UC1, the second undercut structure UC2, and the third undercut structure UC3. These may be derived from the first stack layer IL1. They may contain the same material as the first stack layer IL1.

For example, the first undercut structure UC1 may be located between the first sub-electrode SAND1 and the second sub-electrode SAND2 on one side of the residual pixel defining film. Additionally, the second undercut structure UC2 may be located between the first sub-electrode SAND1 and the second sub-electrode SAND2 on the opposite side of the residual pixel defining film. The second undercut structure UC2 may be formed by one side surface of the residual pixel defining film and the top surface of the first sub-electrode SAND1. In an example, the second undercut structure UC2 may be formed by one side surface of the residual pixel defining film and the bottom surface of the residual second sub-electrode RSAND2.

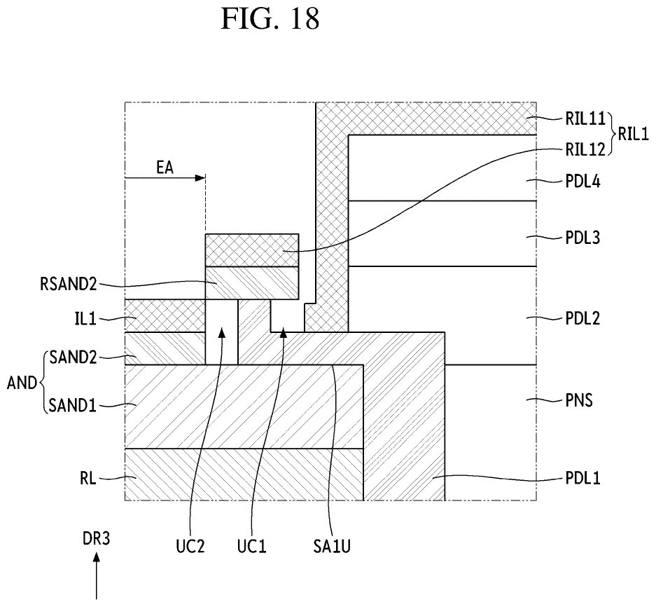

FIG. 18 is a partially enlarged view showing an embodiment of the present disclosure.

Referring to FIG. 18, the embodiment may include the first undercut structure UC1 and the second undercut structure UC2. In the fourth embodiment, an undercut structure may be formed not only on one side but also on the other side of the first pixel defining film PDL1 such as in the second embodiment.

The fourth embodiment may include a residual second sub-electrode RSAND2 including the same material as the second sub-electrode SAND2. The residual second sub-electrode RSAND2 may be derived from the second sub-electrode SAND2.

The fourth embodiment may include the first light emitting stack residual film RIL11 and the second light emitting stack residual film RIL12 by the first undercut structure UC1 and the second undercut structure UC2. These may be derived from the first stack layer IL1. They may contain the same material as the first stack layer IL1.

For example, the first undercut structure UC1 may be located between the first sub-electrode SAND1 and the second sub-electrode SAND2 on one side of the first pixel defining film PDL1. Further, the second undercut structure UC2 may be located between the first sub-electrode SAND1 and the second sub-electrode SAND2 on the opposite side of the first pixel defining film PDL1.

The first pixel defining film PDL1 may include the first side surface of the first pixel defining film PDL1, the second side surface of the first pixel defining film PDL1, and the third side surface of the first pixel defining film PDL1. The first side surface of the first pixel defining film PDL1 may be located between the third side surface and the second side surface of the first pixel defining film PDL1. The third side surface of the first pixel defining film PDL1 may be located closer to the center of the emission area EA than the second side surface of the first pixel defining film PDL1.

The first undercut structure UC1 may be formed by the first side surface of the first pixel defining film PDL1 and the bottom surface of the residual second sub-electrode RSAND2. The second undercut structure UC2 may be formed by the third side surface of the first pixel defining film PDL1 and the bottom surface of the residual second sub-electrode RSAND2.

The embodiments and modified examples described above may be combined or modified in various ways. For example, in the fourth embodiment, a third undercut structure may be separately formed in the second pixel defining film PDL2, the third pixel defining film PDL3, and the fourth pixel defining film PDL4. The naming of the embodiments “first embodiment, second embodiment, third embodiment, etc.” is merely for identification purposes and should not be construed as a limitation on the possible number of implementations.

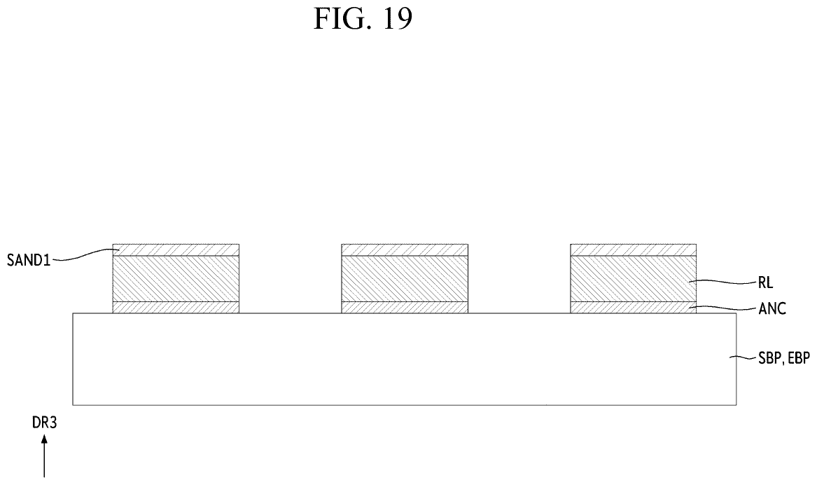

FIGS. 19 to 35 are cross-sectional views illustrating a method of manufacturing a display device according to an embodiment of the present disclosure. Each is divided into a common manufacturing method, a manufacturing method of the first embodiment, a manufacturing method of the second embodiment, and manufacturing methods of the third embodiment and the fourth embodiment.

FIGS. 19 to 27 are cross-sectional views illustrating a common method of manufacturing a display device according to an embodiment of the present disclosure.

Referring to FIG. 19, the plurality of connection electrodes ANC may be spaced apart from each other on the backplanes SBP and EBP. The plurality of reflective electrodes RL and a plurality of first sub-electrodes SAND1 may be formed on the plurality of connection electrodes ANC.

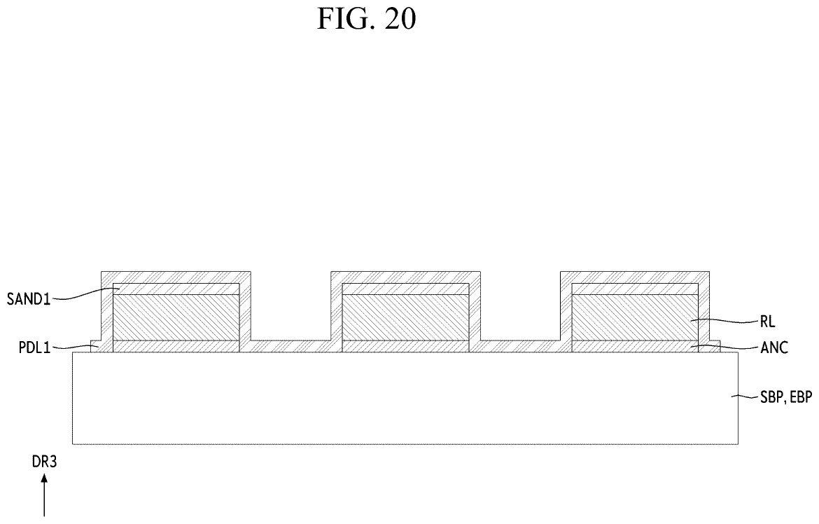

Referring to FIG. 20, the first pixel defining film PDL1 may be located on the plurality of first sub-electrodes SAND1. The first pixel defining film PDL1 may be formed by being connected as one. The first pixel defining film PDL1 may cover the top surfaces of the plurality of first sub-electrodes SAND1. The first pixel defining film PDL1 may be formed to cover the side surfaces of the connection electrode ANC, the reflective electrode RL, and the first sub-electrode SAND1.

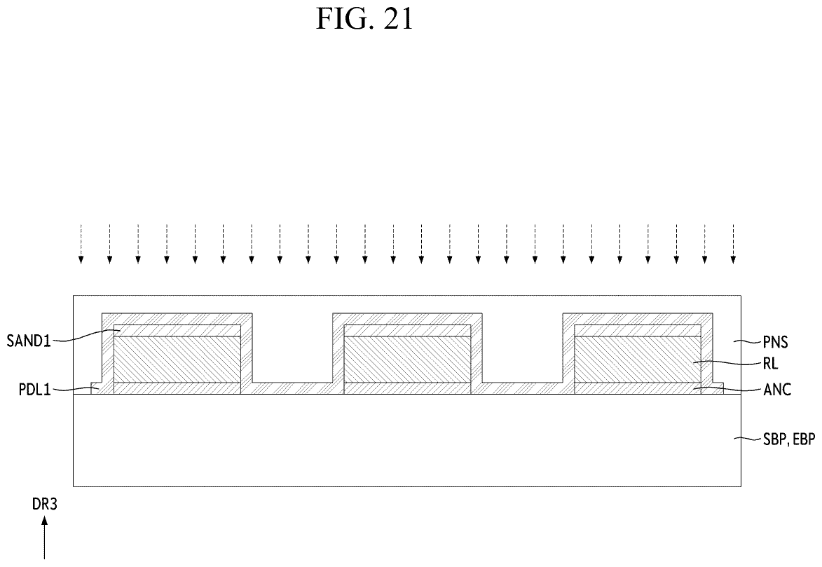

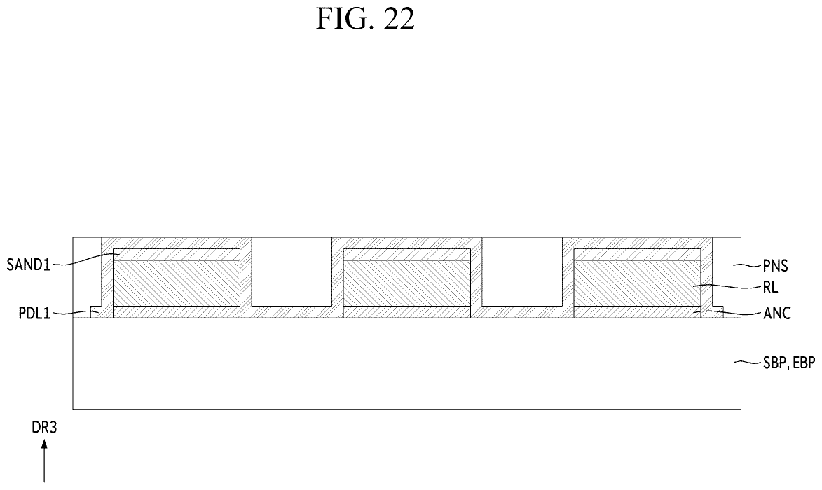

Referring to FIGS. 21 and 22, the planarization film PNS may be formed to cover the first pixel defining film PDL1. The planarization film PNS may be formed to cover both the top surface and the side surface of the first pixel defining film PDL1. Afterwards, at least a part of the planarization film PNS may be removed. After removal, the topmost surface of the planarization film PNS may be aligned in height with the topmost surface of the first pixel defining film PDL1. The first pixel defining film PDL1 may act as a stopper during this process.

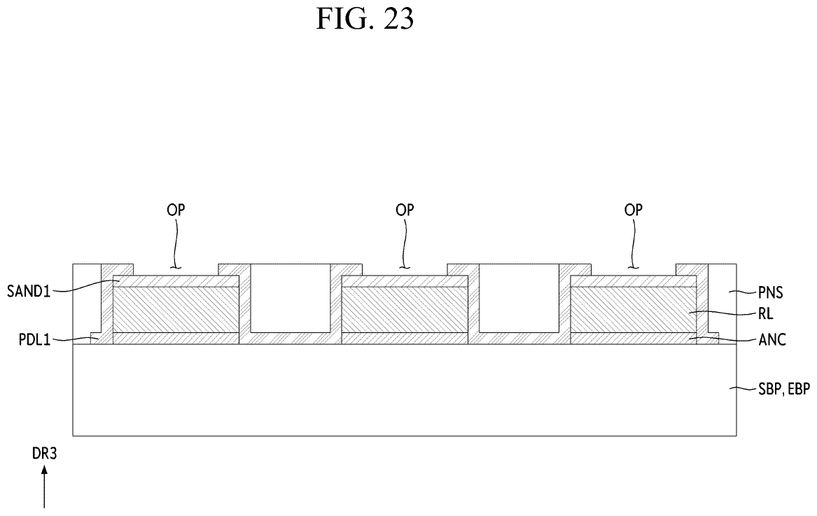

Referring to FIG. 23, an opening OP for exposing the first sub-electrode SAND1 may be formed in the first pixel defining film PDL1. A process of forming the opening OP may be performed utilizing a photo process. When the opening OP is formed, the first pixel defining film PDL1 may have a shape that covers the edge of the first sub-electrode SAND1. The first sub-electrode SAND1 may be exposed at the upper side of the display device through the opening OP.

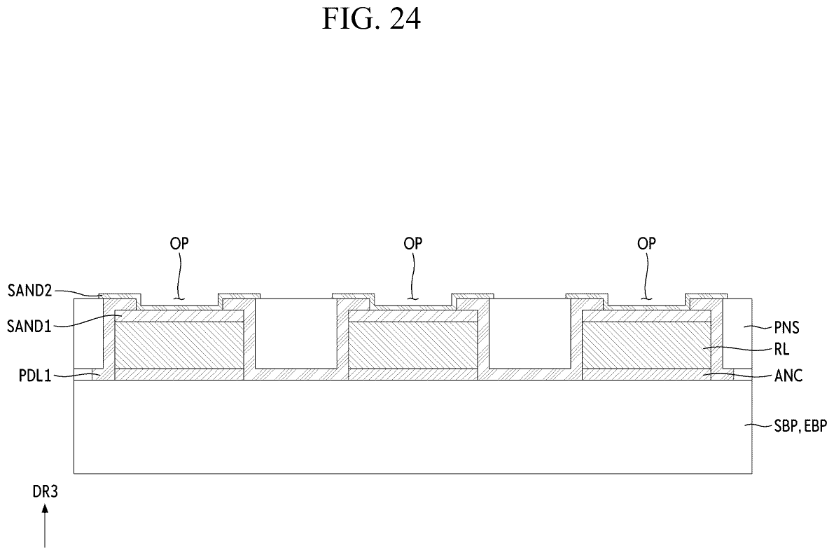

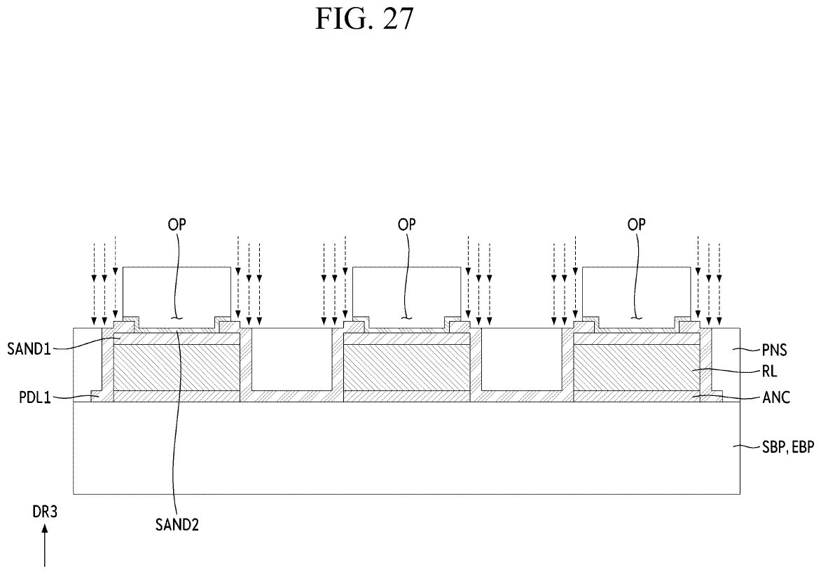

Referring to FIG. 24, the second sub-electrode SAND2 may be formed to cover the first sub-electrode SAND1 and the first pixel defining film PDL1. The second sub-electrode SAND2 may be located to be in contact with the first sub-electrode SAND1 at the opening OP. The second sub-electrode SAND2 may be located to be in contact with the first pixel defining film PDL1 at a portion other than the opening OP. When the planarization film PNS is provided, the second sub-electrode SAND2 may be positioned at a position other than the portion at which the planarization film PNS is located (see FIG. 27).

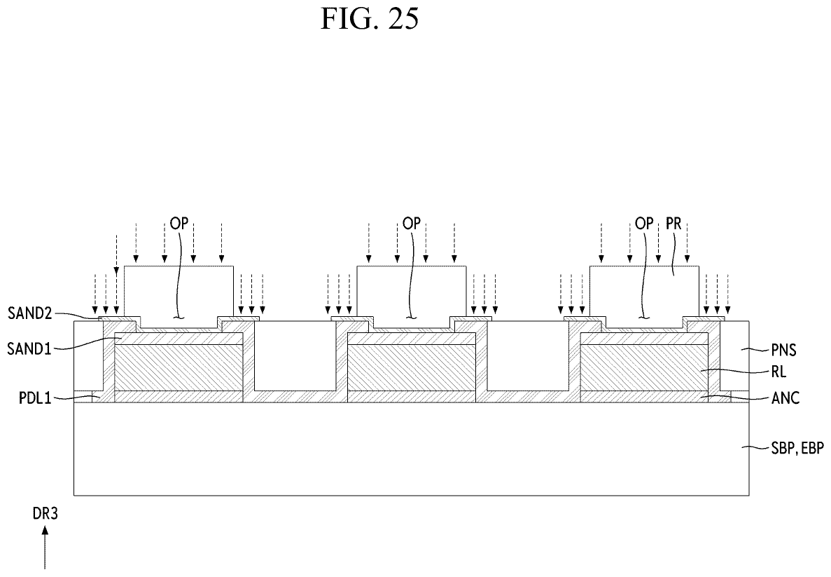

Referring to FIGS. 25, 26, and 27, a plurality of photoresist patterns PR may be spaced apart from each other on the second sub-electrode SAND2. The plurality of photoresist patterns PR may have a pattern shape for etching the second sub-electrode SAND2. The second sub-electrode SAND2 may be removed entirely except for the portion overlapping the photoresist pattern PR.

When the second sub-electrode SAND2 is removed, the first pixel defining film PDL1 and the planarization film PNS may also be removed together. In an embodiment, the operator may change the conditions (or etch selectivity or the like) of the etching process to etch only the first pixel defining film PDL1 or to etch the planarization film PNS together with the first pixel defining film PDL1.

Hereinafter, the first embodiment is a manufacturing method for a case where the first pixel defining film PDL1 and the planarization film PNS are etched together, and the second embodiment is a manufacturing method for a case where only the first pixel defining film PDL1 is etched.

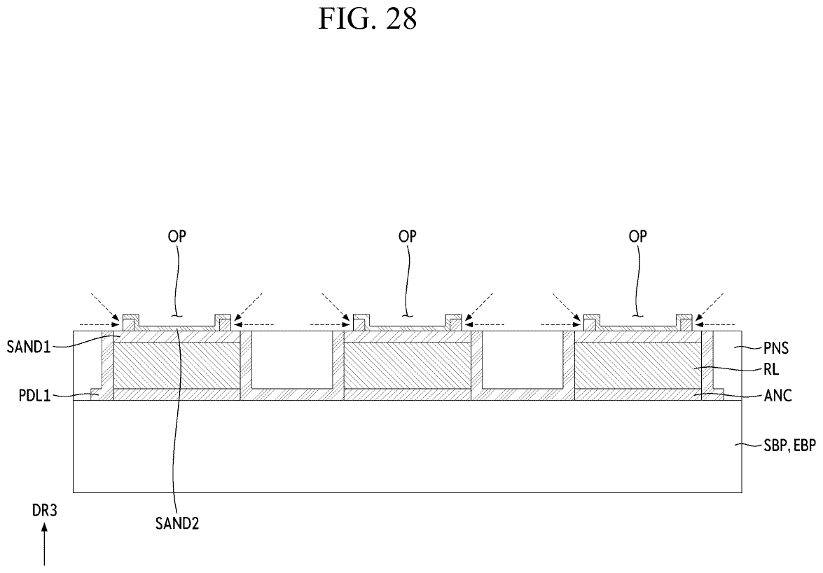

FIGS. 28 to 30 are cross-sectional views illustrating a method of manufacturing the display device according to the first embodiment.

Referring to FIG. 28, when the first pixel defining film PDL1 and the planarization film PNS are etched together, the top surface of the first sub-electrode SAND1, the top surface of the first pixel defining film PDL1, and the top surface of the planarization film PNS may all have the same height. In this case, the residual pixel defining film RPDL1 may be formed by being derived from the first pixel defining film PDL1. The first pixel defining film PDL1 and the residual pixel defining film RPDL1 may be separated from each other, but may contain the same material.

Thereafter, the residual pixel defining film RPDL1 overlapping the second sub-electrode SAND2 in the thickness direction may be etched in the horizontal direction. For example, the residual pixel defining film RPDL1 may be isotropically etched. The etching method may vary, and the residual pixel defining film RPDL1 may have various etching surfaces as described above.

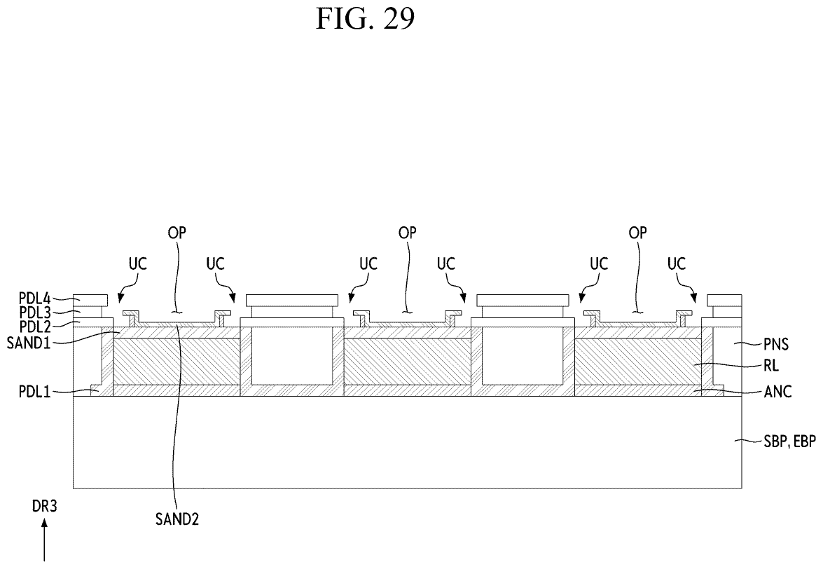

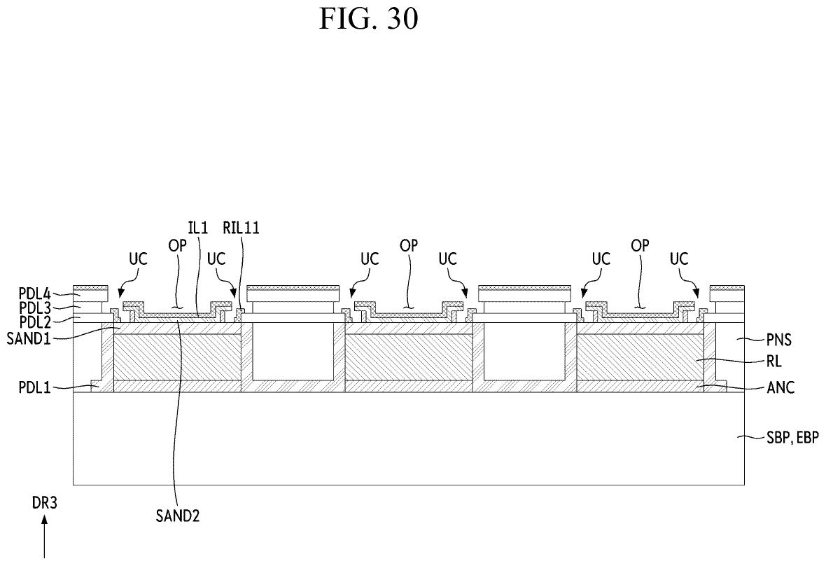

Referring to FIGS. 29 and 30, the second pixel defining film PDL2, the third pixel defining film, and the fourth pixel defining film may be located such that the heights of the top surface of the first sub-electrode SAND1 and the bottom surface of the second pixel defining film PDL2 are identical to each other. Afterwards, a first stack layer may be deposited. The first stack layer may be disconnected during the deposition process due to the undercut structure previously formed. The light emitting stack residual film may be formed by being separated from the first stack layer. The light emitting stack residual film may include a first light emitting stack residual film and a second light emitting stack residual film, but embodiments of the present disclosure are not limited thereto.

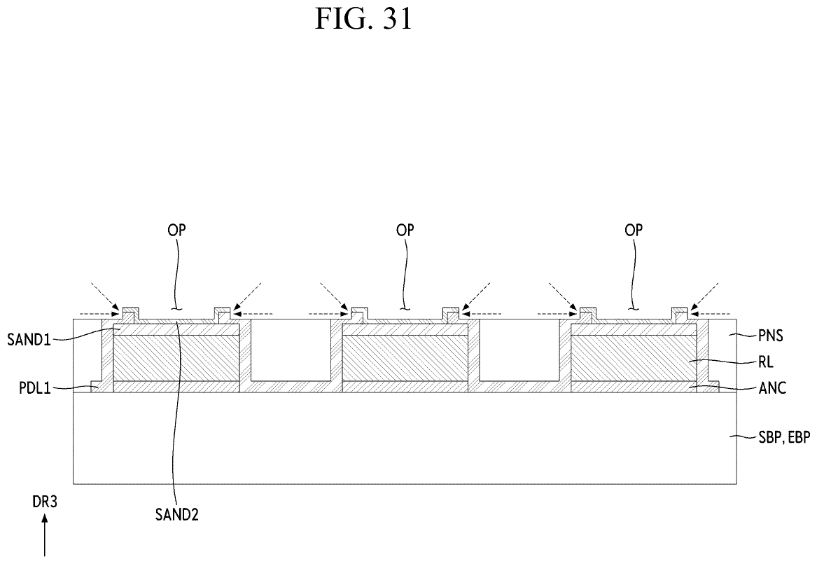

FIGS. 31 to 33 are cross-sectional views illustrating a method of manufacturing the display device according to the second embodiment.

Referring to FIG. 31, when only the first pixel defining film PDL1 is etched, the top surface of the first sub-electrode SAND1, the top surface of the first pixel defining film PDL1, and the top surface of the planarization film PNS may not all have the same height. For example, the top surface height of the first sub-electrode SAND1 may be lower than the top surface height of the planarization film PNS. In this case, the first pixel defining film PDL1 may maintain a connected state.

Thereafter, at least a part of the first pixel defining film PDL1 overlapping the second sub-electrode SAND2 in the thickness direction may be etched in the horizontal direction. For example, the above-mentioned may be etched isotropically. The etching method may vary, and the first pixel defining film PDL1 may have various etching surfaces as described above.

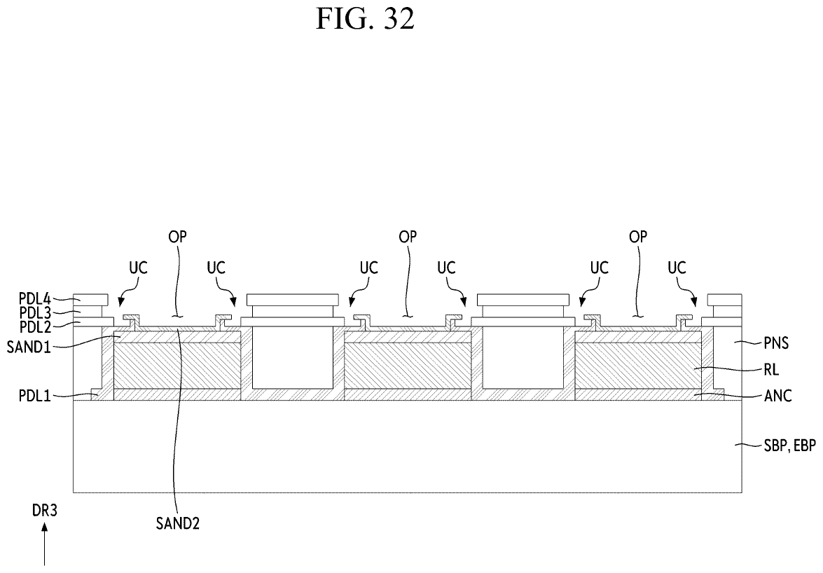

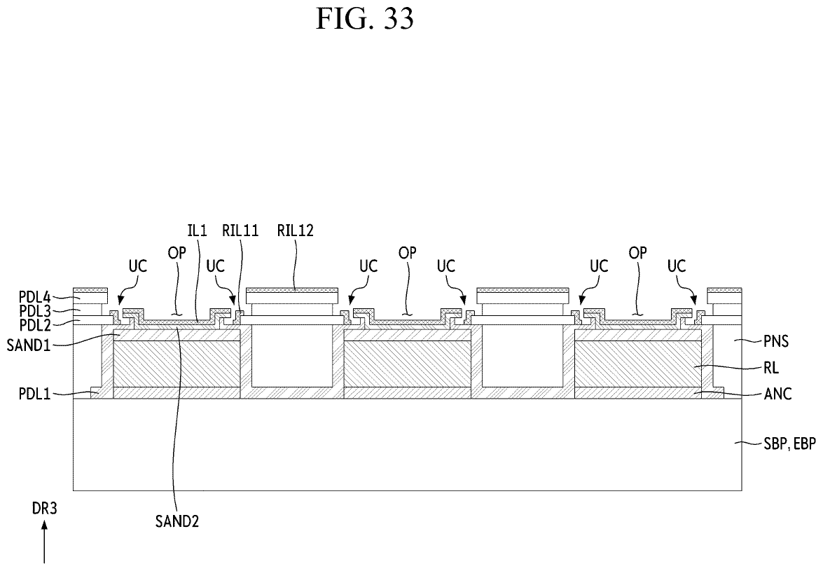

Referring to FIGS. 32 and 33, the second pixel defining film PDL2, the third pixel defining film, and the fourth pixel defining film may be arranged. Afterwards, the first stack layer may be deposited. The first stack layer may be disconnected during the deposition process due to the undercut structure previously formed. The light emitting stack residual film may be formed by being separated from the first stack layer. The light emitting stack residual film may include a first light emitting stack residual film and a second light emitting stack residual film, but embodiments of the present disclosure are not limited thereto.

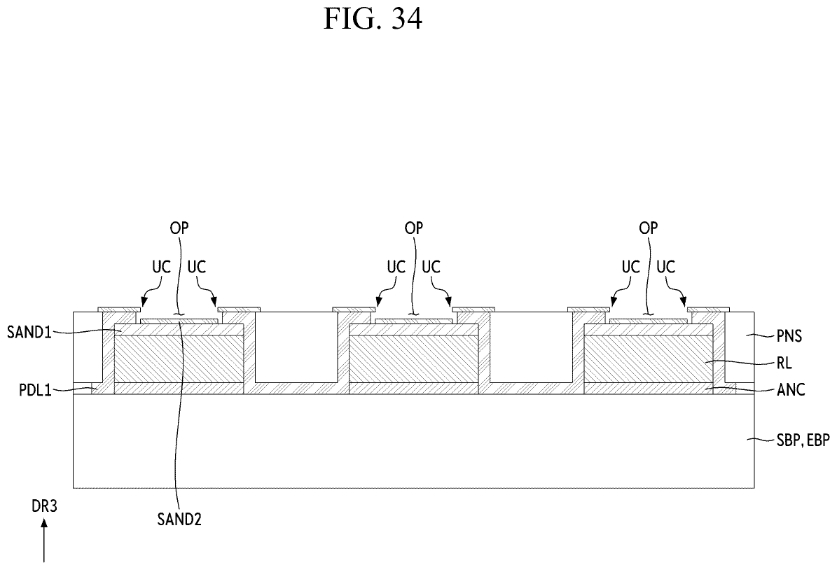

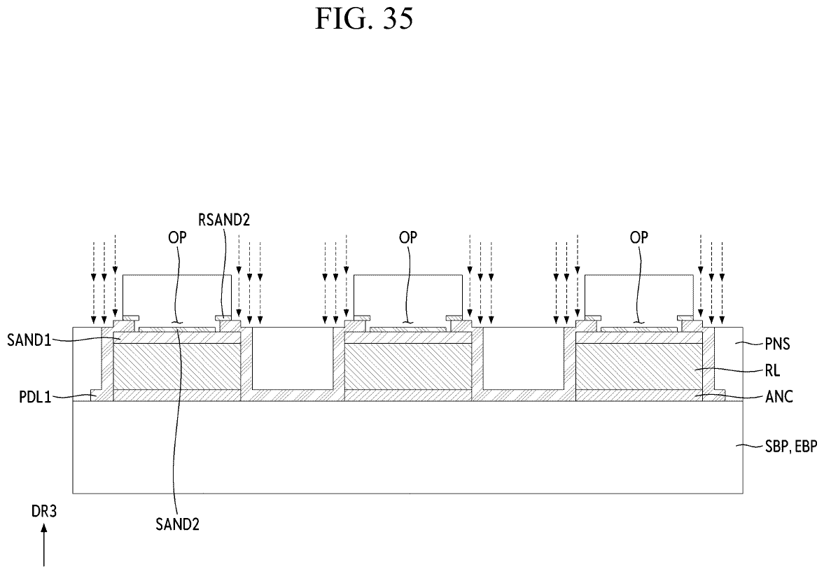

FIGS. 34 and 35 are cross-sectional views illustrating a method of manufacturing the display device according to the third embodiment and the fourth embodiment.

Referring to FIGS. 23, 24, and 34, during the process of forming the second sub-electrode SAND2, the formation may be performed by lowering the step coverage of the second sub-electrode SAND2. In this case, the second sub-electrode SAND2 may be disconnected at one edge of the first pixel defining film PDL1. An undercut structure may be formed as the second sub-electrode SAND2 with low step coverage is formed. The residual second sub-electrode RSAND2 may be formed from the second sub-electrode SAND2.

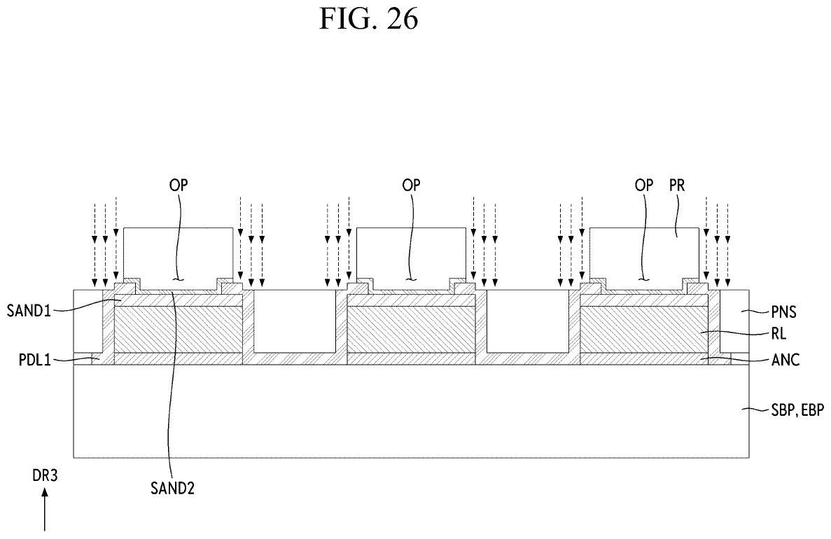

Referring to FIGS. 26 and 35, the process may be similar to that described with reference to FIG. 26, except that the undercut structure is formed using the step coverage.

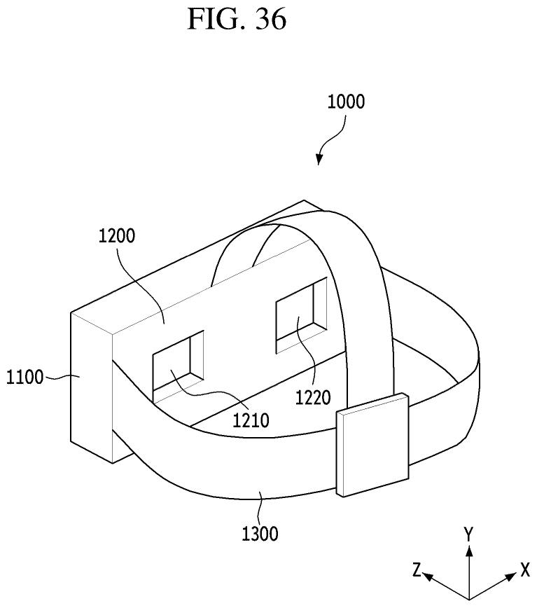

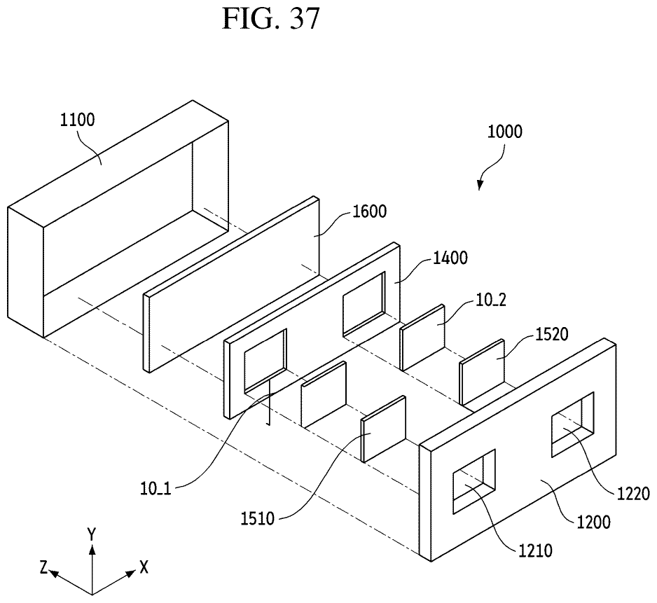

FIG. 36 is a perspective view illustrating a head mounted display according to an embodiment of the present disclosure. FIG. 37 is an exploded perspective view illustrating an example of the head mounted display of FIG. 36.

Referring to FIGS. 36 and 37, a head mounted display 1000 according to an embodiment of the present disclosure includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 8, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source as an input from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In a different example, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 36 and 37 illustrate that the first eyepiece 1210 and the second eyepiece 1220 are located separately, but the embodiment of the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

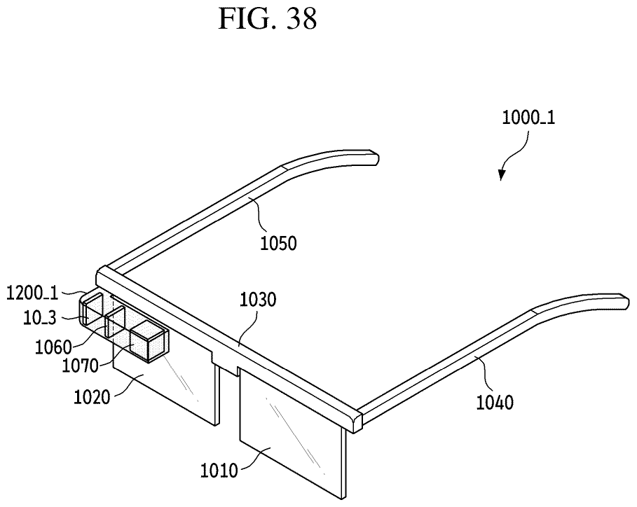

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 38, an eyeglass frame instead of the head mounted band 1300.

FIG. 38 is a perspective view illustrating a head mounted display according to an embodiment of the present disclosure.

Referring to FIG. 38, a head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path is changed by the optical path changing member 1070. As a result, the user may view an augmented reality image, through the right eye, in which a virtual image displayed on the display device 10_3 and a real image seen through the right eye lens 1020 are combined.

FIG. 38 illustrates that the display device housing 1200_1 is located at the right end of the support frame 1030, but the embodiment of the present disclosure is not limited thereto. For example, the display device housing 1200_1 may be located at the left end of the support frame 1030, and in this case, the image of the display device 10_3 may be provided to the user's left eye. In a different example, the display device housing 1200_1 may be located at both the left and right ends of the support frame 1030, and in this case, the user may view the image displayed on the display device 10_3 through both the left and right eyes.

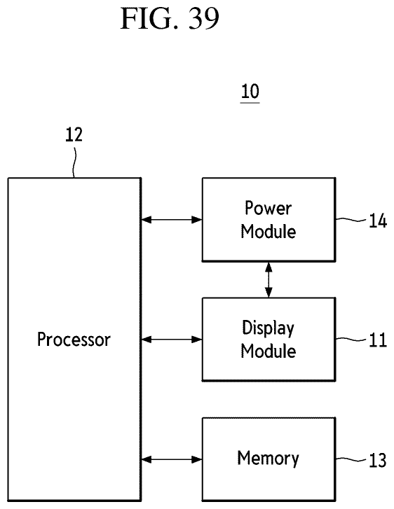

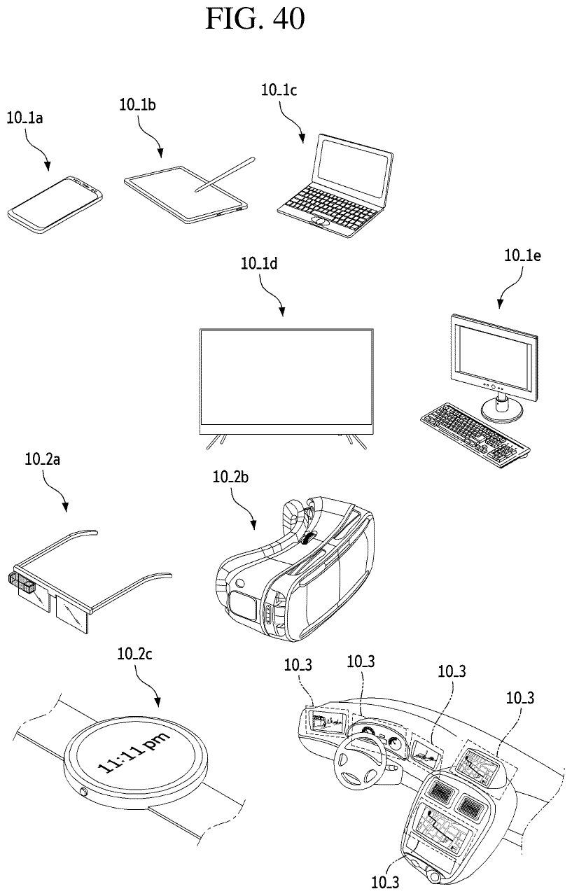

FIG. 39 is a block diagram of an electronic device according to an embodiment of the present disclosure. FIG. 40 is schematic views of electronic devices according to various embodiments of the present disclosure.

Referring to FIG. 39, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. The processor 12 may be one or more processor and the one or more processors may be configured to carry out instructions as individual processors, as a collective or a as a part of the collective (e.g., 2 out of 3 processors perform an instruction together).

The memory 15 may store data information for the operation of the processor 12 or the display module 11. When the processor 12 executes an application stored in the memory 15, an image data signal and/or an input control signal is transmitted to the display module 11, and the display module 11 may process the received signal and output image information through a display screen.

The power module 14 may include a power supply module such as a power adapter or a battery device. The power module 14 may include a power conversion module. The power conversion module may convert the power supplied by the power supply module to generate a power for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device may include the display module 11, whereas the processor 12, the memory 13 and the power module 14 may be provided in the form of other devices in the electronic device, other than the display device.

Referring to FIG. 40, various electronic devices to which the display device according to the embodiments of the present disclosure is applied may include electronic devices for displaying images, such as a smartphone 10_1a, a tablet PC 10_1b, a laptop 10_1c, a television (TV) 10_1d, a desk monitor 10_1e, and the like. In addition, various electronic devices to which the display device according to the embodiments of the present disclosure is applied may include a wearable electronic device including a display module, such as smart glasses 10_2a, a head mounted display 10_2b, a smart watch 10_2c, or the like, a vehicle electronic device 10_3 including a display module, such as a center information display (CID) placed on a dashboard, a center fascia, and an instrument panel of a car, a room mirror display, or the like.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not intended to be limiting.

What is claimed is:

1. A display device comprising:
a first electrode comprising a first sub-electrode and a second sub-electrode located on the first sub-electrode;
a light emitting stack located on the first electrode;
a second electrode located on the light emitting stack; and
a first residual film located between the first sub-electrode and the second sub-electrode.

2. The display device of claim 1, wherein at least a part of a bottom surface of the second sub-electrode is exposed by the first residual film.

3. The display device of claim 1, wherein an undercut structure is located between the first sub-electrode and the second sub-electrode on one side of the first residual film.

4. The display device of claim 1, wherein one side surface of the first residual film is located closer to a center of an emission area than a first side surface of the second sub-electrode.

5. The display device of claim 3, wherein on one side of the first residual film, a bottom surface of the second sub-electrode and one side surface of the first residual film comprise the undercut structure.

6. The display device of claim 3, wherein on one side of the first residual film, a top surface of the first sub-electrode and one side surface of the first residual film comprise the undercut structure.

7. The display device of claim 1, further comprising a first pixel defining film located on one side of the first sub-electrode,
wherein the first residual film and the first pixel defining film include a same material.

8. The display device of claim 1, wherein a first undercut structure is located between the first sub-electrode and the second sub-electrode on one side of the first residual film, and
a second undercut structure is located between the first sub-electrode and the second sub-electrode on an opposite side of the first residual film.

9. A display device comprising:
a first electrode comprising a first sub-electrode and a second sub-electrode located on the first sub-electrode;
a light emitting stack located on the first electrode;
a second electrode located on the light emitting stack; and
a first pixel defining film located between the first sub-electrode and the second sub-electrode,
wherein at least a part of a bottom surface of the second sub-electrode is located to be in contact with the first pixel defining film.

10. The display device of claim 9, wherein at least a part of the bottom surface of the second sub-electrode is exposed by the first pixel defining film.

11. The display device of claim 9, wherein an undercut structure is located between the first sub-electrode and the second sub-electrode on one side of the first pixel defining film.

12. The display device of claim 11, wherein the first pixel defining film comprises:
a first side surface; and
a second side surface located further away from a center of an emission area than the first side surface,
wherein the first side surface of the first pixel defining film and the bottom surface of the second sub-electrode comprise the undercut structure.

13. The display device of claim 12, wherein the first pixel defining film comprises:
a first top surface; and
a second top surface located further away from a topmost surface of the second sub-electrode than the first top surface,
wherein the first side surface, the second top surface of the first pixel defining film and the bottom surface of the second sub-electrode comprise the undercut structure.

14. The display device of claim 11, wherein on one side of the first pixel defining film, one side surface of the first pixel defining film and a top surface of the first sub-electrode comprise the undercut structure.

15. The display device of claim 9, wherein a first undercut structure is located between the first sub-electrode and the second sub-electrode on one side of the first pixel defining film, and
a second undercut structure is located between the first sub-electrode and the second sub-electrode on an opposite of the first pixel defining film.

16. The display device of claim 15, wherein the first pixel defining film comprises:
a first side surface;
a second side surface located further away from a center of an emission area than the first side surface; and
a third side surface located closer to the center of the emission area than the first side surface,
wherein the first side surface of the first pixel defining film and the bottom surface of the second sub-electrode comprise the first undercut structure, and
the third side surface of the first pixel defining film and the bottom surface of the second sub-electrode comprise the second undercut structure.

17. An electronic device comprising:
one or more processors providing an image signal;
a display module receiving the image signal from the processor and displaying an image; and
a power module supplying power to the display module,
wherein the display module comprises:
a first electrode comprising a first sub-electrode and a second sub-electrode located on the first sub-electrode;
a light emitting stack located on the first electrode;
a second electrode located on the light emitting stack; and
a first residual film located between the first sub-electrode and the second sub-electrode or a first pixel defining film located between the first sub-electrode and the second sub-electrode.

18. The electronic device of claim 17, including a first residual film located between the first sub-electrode and the second sub-electrode and wherein at least a part of a bottom surface of the second sub-electrode is exposed by the first residual film.

19. The electronic device of claim 17 including a first pixel defining film located between the first sub-electrode and the second sub-electrode, and
wherein at least a part of a bottom surface of the second sub-electrode is located to be in contact with the first pixel defining film.

20. The electronic device of claim 19, wherein at least a part of the bottom surface of the second sub-electrode is exposed by the first pixel defining film.
